(19) United States
(12) Patent Application Publication
(10) Pub. No.: US 2026/0033099 A1
(43) Pub. Date: Jan. 29, 2026

(54) DISPLAY PANEL AND METHOD OF MANUFACTURING THE SAME AND DISPLAY DEVICE INCLUDING THE SAME

(71) Applicant: LG DISPLAY CO., LTD., Seoul (KR)

(72) Inventors: Jeen Wook KWON, Paju-si (KR); Kyoung June JUNG, Paju-si (KR); Dae Han WON, Paju-si (KR); Chan Woo IM, Paju-si (KR)

(73) Assignee: LG DISPLAY CO., LTD., Seoul (KR)

(21) Appl. No.: 19/251,563

(22) Filed: Jun. 26, 2025

(30) Foreign Application Priority Data
Jul. 26, 2024 (KR) 10-2024-0099534

(51) Int. Cl. H10H 29/854; H10H 29/01

(52) U.S. Cl. CPC H10H 29/854; H10H 29/012

(57) ABSTRACT

A display panel may include a substrate, a circuit layer disposed on the substrate, a plurality of light-emitting elements disposed on the circuit layer and electrically connected to the circuit layer, an optical layer surrounding the light-emitting elements, a first inorganic film layer disposed on the optical layer, and a second inorganic film layer disposed under the optical layer. Insulating layers of the circuit layer and a side surface of the optical layer may be exposed on at least one of side surfaces of the substrate, and a stepped portion of the optical layer may be present between outermost ends of the first inorganic film layer and the second inorganic film layer and at least one of outermost side surfaces of the substrate. A method of manufacturing a display panel and a display device include a display panel are also disclosed.

### CROSS-REFERENCE TO RELATED APPLICATION

This application claims the benefit of and priority to Korean Patent Application No. 10-2024-0099534, filed on Jul. 26, 2024, the entire contents of which are incorporated herein by reference for all purposes.

### BACKGROUND

### 1. Technical Field

The present disclosure relates to a display panel and a method of manufacturing the same and a display device including the same.

### 2. Description of Related Art

Display devices are being applied to various electronic devices such as a television (TV), a mobile phone, a notebook, a tablet, and the like.

Display devices include an organic light-emitting display (OLED) device which emits light by itself, a liquid crystal display (LCD) device which requires a separate light source, and the like.

Recently, display devices including light-emitting elements (for example, light-emitting diodes, LEDs) are attracting attention as next generation display devices. The light-emitting elements are formed of an inorganic material rather than an organic material, and thus the display devices including light-emitting elements may have a faster lighting speed and higher luminous efficacy, and display higher brightness images compared to an LCD device or OLED device.

When cutting a display panel into cell units on a mother substrate, film peeling may occur due to poor adhesion between an inorganic material layer and an organic material layer. Due to such film peeling, moisture or the like may penetrate from the outside.

When external particles such as penetrating moisture and the like accumulate in the display device, since technical problems such as reduced reliability and the like may occur, solutions therefor are required.

The description of related art should not be considered prior art merely because it is mentioned in or associated with this section. The description of related art includes information that describes one or more aspects of the subject technology, and the description in this section does not limit the scope of the invention.

### SUMMARY

As described above, since light-emitting elements are not transferred to a display region disposed near a non-display region in a display device including inorganic light-emitting elements (for example, micro light-emitting diodes (micro LEDs)), the reliability of the display device may decrease.

An embodiment of the present disclosure is directed to providing a display panel whose process reliability is enhanced and a method of manufacturing the same and a display device including the same.

An embodiment of the present disclosure is directed to providing a display panel whose operation reliability is enhanced and a method of manufacturing the same and a display device including the same.

The aspects according to embodiments of the present disclosure are not limited to the above-described aspects, and other aspects that are not mentioned will be clearly understood by those skilled in the art from the following description.

A display panel according to an embodiment of the present disclosure includes a substrate, a circuit layer disposed on the substrate, a plurality of light-emitting elements disposed on the circuit layer and electrically connected to the circuit layer, an optical layer surrounding the light-emitting elements, a first inorganic film layer disposed on the optical layer, and a second inorganic film layer disposed under the optical layer, wherein insulating layers of the circuit layer and a side surface of the optical layer are exposed on at least one of side surfaces of the substrate, and wherein a stepped portion of the optical layer is present between outermost ends of the first inorganic film layer and the second inorganic film layer and at least one of outermost side surfaces of the substrate.

In another aspect of the present invention, there is provided a method of manufacturing a display panel, comprising: disposing a circuit layer on a mother substrate; disposing a plurality of light-emitting elements electrically connected to the circuit layer on the circuit layer; disposing a second inorganic film layer on the circuit layer; disposing an optical layer on the second inorganic film layer and the circuit layer to surround the light-emitting elements; disposing a first inorganic film layer on the optical layer; and cutting the mother substrate, the circuit layer, the second inorganic film layer, the optical layer, and the first inorganic film layer with a laser beam along a preset intercell boundary line to separate a plurality of display panels from the mother substrate, wherein insulating layers of the circuit layer and a side surface of the optical layer are exposed on at least one of surfaces of each of the display panels, and wherein a stepped portion of the optical layer is present between outermost ends of the first inorganic film layer and the second inorganic film layer and at least one of side surfaces of the mother substrate.

In another aspect of the present invention, there is provided a display device, comprising the display panel as described above; a polarization layer disposed on the display panel; and a cover member disposed on the polarization layer.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is an exploded perspective view of a display device according to an embodiment of the present disclosure;

FIG. 2 is a plan view showing the display device according to the embodiment of the present disclosure;

FIG. 3 is an enlarged view showing the display device according to the embodiment of the present disclosure;

FIG. 4 is a plan view showing the display device according to the embodiment of the present disclosure;

FIG. 5 is a view showing a circuit structure according to the embodiment of the present disclosure;

FIG. 6 is a partially enlarged view showing portion A in FIG. 3;

FIG. 7 is an enlarged view of a display region including one pixel according to the embodiment of the present disclosure;

FIG. 8 is a partially enlarged view showing portion A in FIG. 3;

FIG. 9 is a cross-sectional view of the display device according to the embodiment of the present disclosure taken along line I-I′ in FIG. 4;

FIG. 10 is a cross-sectional view showing a subpixel including light-emitting elements disposed in a display region;

FIG. 11 is a view showing a plurality of cells formed on a mother substrate;

FIG. 12 is an enlarged plan view showing portion C in FIG. 11;

FIG. 13 is a cross-sectional view of the display device according to the embodiment of the present disclosure taken along line II-II′ in FIG. 12;

FIG. 14 is an enlarged cross-sectional view showing portion D in FIG. 13;

FIG. 15 is a cross-sectional view of a display device according to another embodiment of the present disclosure taken along line II-II′ in FIG. 12;

FIG. 16 is a view showing a device to which the display devices according to embodiments of the present disclosure are applied;

FIG. 17 is a view showing a device to which the display devices according to the embodiments of the present disclosure are applied;

FIG. 18 is a view showing a device to which the display devices according to the embodiments of the present disclosure are applied; and

FIG. 19 is a view showing a device to which the display devices according to the embodiments of the present disclosure are applied.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure and methods of achieving them will become apparent with reference to the following embodiments, which are described in detail, in conjunction with the accompanying drawings. However, the present disclosure is not limited to the embodiments to be described below and may be implemented in various different forms, the embodiments are only provided to completely disclose the present disclosure and completely convey the scope of the present disclosure to those skilled in the art.

Since the shapes, sizes, proportions, angles, numbers, and the like disclosed in the drawings for describing the embodiments of the present disclosure are only examples, the present disclosure is not limited to the items shown in the drawings. The same reference number indicates the same components throughout the specification. Further, in describing the present disclosure, when it is determined that a detailed description of related known technology may unnecessarily obscure the gist of the present disclosure, the detailed description thereof will be omitted. When “providing,” “including,” “having,” “comprising,” and the like are used herein, other parts may be added unless ‘only’ is used. A case in which a component is expressed in a singular form may include a plural form unless explicitly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In interpreting a component, the component is interpreted as including a margin of error even when there is no separate explicit description of the margin of error.

In a description of a positional relationship, for example, when the positional relationship of two parts by using terms such as “on,” “at an upper portion,” “at a lower portion,” “next to,” “adjacent to,” or the like is described, one or more other parts may be located between the two parts unless “immediately,” “directly,” or “close to” is used.

In a description of a temporal relationship, when the temporal relationship is described by using terms such as “after,” “following,” “and then,” “before,” or the like, non-consecutive cases may also be included unless “immediately” or “directly” is used.

Although first, second, and the like are used to describe various components, these components are not limited by these terms. These terms are only used to distinguish one component from another component. Accordingly, a first component described below may also be a second component within the technical spirit of the present disclosure.

Terms, such as first, second, A, B, (a), and (b) may be used to describe components of the present disclosure. These terms are only for the purpose of distinguishing one component from another component, and the nature, sequence, order, or the like of the corresponding components is not limited by these terms.

When a component is described as being “connected,” “coupled,” “linked,” or “attached” to another component, it should be understood that the component may be directly connected, coupled, linked, or attached to the other component, but another component may be interposed between the components which may be indirectly connected, coupled, linked, or attached to each other unless explicitly stated otherwise.

When a component or layer is described as “overlapping” another component or layer, it should be understood that the component or layer may be in direct contact with or directly overlap another component or layer, but another component may be interposed between the components which may indirectly overlap each other unless explicitly stated otherwise.

“At least one” should be understood as including a combination of one or more of the related components. For example, the term “at least one of first, second, and third components” includes not only the first, second, or third component, but also all combinations of two or more of the first, second, and third components.

The terms “first direction,” “second direction,” “third direction,” “X-axis direction,” “Y-axis direction,” and “Z-axis direction” should not be understood as only a geometric relationship in which relationships therebetween are perpendicular to each other, but mean that a configuration of the present disclosure has a broader directionality within a range in which it may functionally act.

Features of various embodiments of the present disclosure may be partially or entirely combined with each other, and technically, various interconnections and operations are possible, and the embodiments may be implemented independently of each other or together in a related relationship.

Hereinafter, various embodiments of the present disclosure will be described in detail with reference to the accompanying drawings.

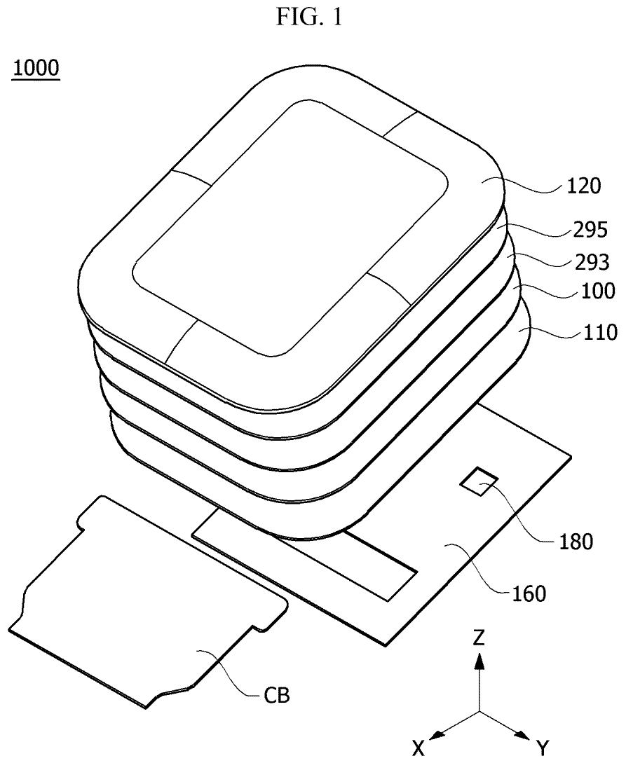

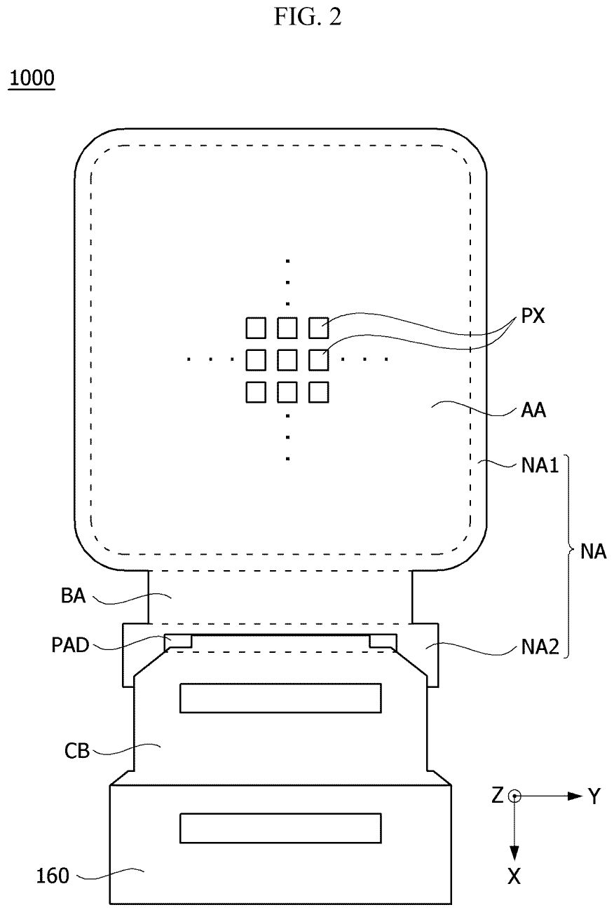

FIG. 1 is an exploded perspective view showing a display device according to an embodiment of the present disclosure. FIG. 2 is a plan view showing the display device according to the embodiment of the present disclosure.

Referring to FIGS. 1 to 2, a display device 1000 according to the embodiment of the present disclosure may include a display panel 100, a polarization layer 293, a second adhesive layer 295, a cover member 120, a substrate 110, a flexible circuit board CB, and a printed circuit board 160.

For example, the display device 1000 may include the substrate 110. The substrate 110 may be a member which supports other components of the display device 1000. The substrate 110 may be formed of an insulating material. For example, the substrate 110 may be formed of glass, a resin, or the like. Further, the substrate 110 may be formed of a material having flexibility. For example, the substrate 110 may be formed of a plastic material having flexibility such as polyimide (PI) or the like. However, the embodiments of the present disclosure are not limited thereto.

The display panel 100 may implement information, a video, and/or an image provided to a user. For example, the display panel 100 may include a display region AA and a non-display region NA. For example, the substrate 110 may include the display region AA and the non-display region NA. The display region AA and the non-display region NA are not limited to the substrate 110 but may be provided throughout the display device 1000.

The display region AA may be a region where an image is displayed. The display region AA may include a plurality of pixels PX. Each of the plurality of pixels PX may be composed of a plurality of subpixels. A plurality of light-emitting elements may be disposed in each of the plurality of subpixels. The plurality of light-emitting elements may be configured differently depending on the type of display device 1000. For example, when the display device 1000 is an inorganic light-emitting display device, the light-emitting element may be a light-emitting diode (LED), a micro light-emitting diode (micro LED), or a mini light-emitting diode (mini LED), but the embodiments of the present disclosure are not limited thereto.

The non-display region NA may be a region where an image is not displayed. Various lines and circuits for driving the plurality of pixels PX of the display region AA may be disposed in the non-display region NA. For example, in the non-display region NA, various lines and driving circuits may be mounted, and a pad portion PAD to which an integrated circuit, a printed circuit, and the like are connected may be disposed, but the embodiments of the present disclosure are not limited thereto.

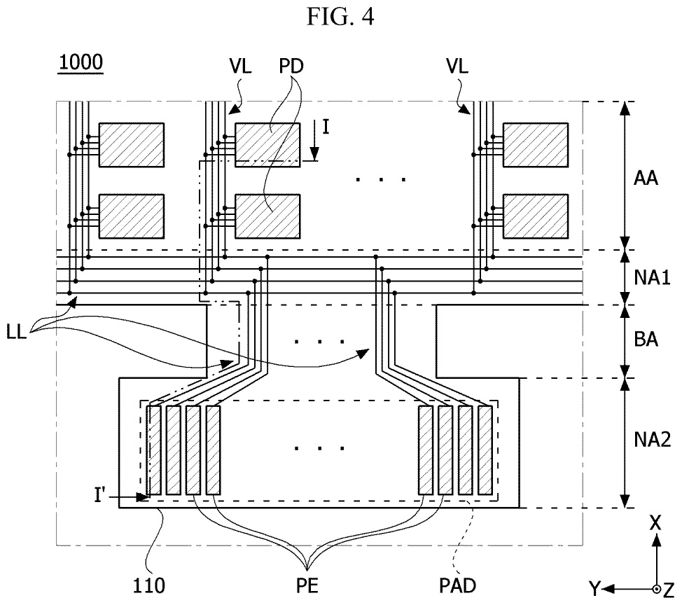

For example, the driving circuit may be a data driving circuit and/or a gate driving circuit, but the embodiments of the present disclosure are not limited thereto. Lines through which control signals for controlling the driving circuits are supplied may be disposed on the display panel 100. For example, the control signals may include various timing signals including a clock signal, an input data enable signal, and a synchronization signal, but the embodiments of the present disclosure are not limited thereto. The control signals may be received through the pad portion PAD. For example, link lines LL (see FIG. 4) for transmitting signals may be disposed in the non-display region NA. For example, driving components such as the flexible circuit board CB and the printed circuit board 160 may be connected to the pad portion PAD.

According to the present disclosure, the non-display region NA may include a first non-display region NA1, a bending region BA, and a second non-display region NA2. For example, the first non-display region NA1 may be a region surrounding at least a portion of the display region AA. The bending region BA may be a region extending from at least one side of a plurality of sides of the first non-display region NA1 and may be a bendable region. The second non-display region NA2 may be a region extending from the bending region BA, and the pad portion PAD may be disposed in the second non-display region NA2. For example, the bending region BA may be in a bent state, and the remaining region of the substrate 110 excluding the bending region BA may be in a flat state. In this case, as the bending region BA is bent, the second non-display region NA2 may be located on a rear surface of the display region AA. However, the embodiments of the present disclosure are not limited thereto.

The display region AA of the substrate 110 or the display device 1000 may be configured in various shapes depending on the design of the display device 1000. For example, the display region AA may be configured in a rectangular shape whose four corners are formed in a round shape, but the embodiments of the present disclosure are not limited thereto. For another example, the display region AA may be configured in a rectangular shape whose four corners are formed in a right-angled shape, a circular shape, or the like, but the embodiments of the present disclosure are not limited thereto.

According to the present disclosure, a width of the second non-display region NA2 where a plurality of pad electrodes PE are disposed may be wider than a width of the bending region BA where only a plurality of link lines LL are disposed. Further, a width of the display region AA where the plurality of subpixels are disposed may be wider than the width of the bending region BA where only the plurality of link lines LL are disposed. The drawings show that the width of the bending region BA is narrower than widths of other regions of the substrate 110, but a shape of the substrate 110 including the bending region BA is an example, and the embodiments of the present disclosure are not limited thereto.

The flexible circuit board CB and the printed circuit board 160 may be disposed under the display panel 100. The flexible circuit board CB and the printed circuit board 160 may be disposed on at least an edge of one side of the display panel 100, but the embodiments of the present disclosure are not limited thereto. One side of the flexible circuit board CB may be attached to the display panel 100 and the other side may be attached to the printed circuit board 160, but the embodiments of the present disclosure are not limited thereto. The flexible circuit board CB may be a flexible film, but the embodiments of the present disclosure are not limited thereto.

The pad portion PAD including a plurality of pad electrodes PE may be disposed in the second non-display region NA2. Driving components including one or more flexible circuit boards (or flexible films) CB and the printed circuit board 160 may be attached or bonded to the pad portion PAD. The plurality of pad electrodes PE of the pad portion PAD are electrically connected to one or more flexible circuit boards (or flexible films) CB, and various signals (or power) from the printed circuit board 160 and the flexible circuit boards (or flexible films) CB may be transmitted to the plurality of pixel driving circuits PD of the display region AA.

The flexible circuit board (or flexible film) CB may be a film in which various components are disposed on a flexible base film. For example, a driving integrated circuit (IC) such as a gate driver IC or a data driver IC may be disposed on the flexible circuit board (or flexible film) CB, but the embodiments of the present disclosure are not limited thereto. The driving IC may be a component which processes data and a driving signal for displaying an image. The driving IC may be disposed in a manner such as a chip on glass (COG), a chip on film (COF), a tape carrier package (TCP), or the like depending on a mounting method, but the embodiments of the present disclosure are not limited thereto. The flexible circuit board (or flexible film) CB may be attached or bonded to the plurality of pad electrodes PE through a conductive adhesive layer, but the embodiments of the present disclosure are not limited thereto.

The printed circuit board 160 may be a component which is electrically connected to one or more flexible circuit boards (or flexible films) CB and supplies a signal to the driving IC. The printed circuit board 160 may be disposed on one side of the flexible circuit board (or flexible film) CB and may be electrically connected to the flexible circuit board (or flexible film) CB. Various components for supplying various signals to the driving IC may be disposed on the printed circuit board 160. For example, various components such as a timing controller, a power supply, a memory, a processor, and the like may be disposed on the printed circuit board 160. For example, the printed circuit board 160 may include a power management integrated circuit (PMIC), but the embodiments of the present disclosure are not limited thereto.

The printed circuit board 160 may include at least one hole 180, but the embodiments of the present disclosure are not limited thereto. An internal component which detects ambient light, temperature, or the like which may be provided to a plurality of sensors may be disposed in a region corresponding to the at least one hole 180. For example, the internal component may include an ambient light sensor (ALS) or a temperature sensor, but the embodiments of the present disclosure are not limited thereto. For example, the hole 180 may be a through hole or the like, but the embodiments of the present disclosure are not limited thereto.

The polarization layer 293 may be disposed on the display panel 100. The polarization layer 293 may prevent or reduce the light generated from an external light source from entering the display panel 100 and affecting the light-emitting element or the like.

The cover member 120 may be disposed on the polarization layer 293. The cover member 120 may be a member for protecting the display panel 100. The second adhesive layer 295 may be disposed between the polarization layer 293 and the cover member 120. The cover member 120 may be attached to the display panel 100 by the second adhesive layer 295. The second adhesive layer 295 may include an optically clear adhesive (OCA), an optically clear resin (OCR), a pressure sensitive adhesive (PSA), or the like, but the embodiments of the present disclosure are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present disclosure are not limited thereto.

A plurality of link lines LL may be disposed in the first and second non-display regions NA1 and NA2. The plurality of link lines LL may be lines which transmit various signals from one or more flexible circuit boards (or flexible films) CB and the printed circuit board 160 to the display region AA. The plurality of link lines LL may extend from the plurality of pad electrodes PE of the second non-display region NA2 toward the bending region BA and the first non-display region NA1 and may be electrically connected to a plurality of connection lines VL of the display region AA. The plurality of pixel driving circuits PD may be driven by receiving signals from one or more flexible circuit boards (or flexible films) CB and the printed circuit board 160 through the connection lines VL of the display region AA and the link lines LL of the non-display region NA.

For example, the plurality of connection lines VL may be lines for transmitting the signals output from the flexible circuit boards (or flexible films) CB and the printed circuit board 160 to the plurality of pixel driving circuits PD along with the plurality of link lines LL. The plurality of connection lines VL may be disposed in the display region AA and may be electrically connected to each of the plurality of pixel driving circuits PD. The plurality of connection lines VL may extend from the display region AA toward the non-display region NA and may be electrically connected to the plurality of link lines LL. Accordingly, the signals output from the flexible circuit boards (or flexible films) CB and the printed circuit board 160 may be respectively transmitted to the plurality of pixel driving circuits PD through the plurality of link lines LL and the plurality of connection lines VL.

As the bending region BA is bent, portions of the plurality of link lines LL may also be bent along with the bending region BA. Stress may be concentrated on portions of the bent link lines LL, and accordingly, cracks may occur in the link lines LL. Accordingly, the plurality of link lines LL may be composed of a conductive material having excellent flexibility to reduce cracks when the bending region BA is bent. For example, the plurality of link lines LL may be composed of a conductive material having excellent flexibility such as gold (Au), silver (Ag), aluminum (Al), or the like, but the embodiments of the present disclosure are not limited thereto. Further, the plurality of link lines LL may be composed of one of various conductive materials used in the display region AA. For example, the plurality of link lines LL may be composed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto. The plurality of link lines LL may be formed in a multi-layer structure including various conductive materials. For example, the plurality of link lines LL may be configured in a triple-layer structure of titanium (Ti)/aluminum (Al)/titanium (Ti), but the embodiments of the present disclosure are not limited thereto.

The plurality of link lines LL may be configured in various shapes to reduce stress. At least portions of the plurality of link lines LL disposed on the bending region BA may extend in the same direction as an extending direction of the bending region BA, or may extend in a different direction from the extending direction of the bending region BA to reduce stress. For example, when the bending region BA extends in one direction from the first non-display region NA1 toward the second non-display region NA2, at least portions of the link lines LL disposed on the bending region BA may extend in a direction oblique to the one direction. For another example, at least portions of the plurality of link lines LL may be configured in various pattern shapes. For example, at least portions of the plurality of link lines LL disposed on the bending region BA may have a shape in which a conductive pattern having at least one of a diamond shape, a rhombus shape, a trapezoidal wave shape, a triangular wave shape, a sawtooth wave shape, a sine wave shape, a circular shape, and an omega (Ω) shape is repeatedly disposed, but the embodiments of the present disclosure are not limited thereto. Accordingly, in order to minimize the stress concentrated on the plurality of link lines LL and cracks resulting from the stress, the plurality of link lines LL may be formed in various shapes including the above-described shapes, but the embodiments of the present disclosure are not limited thereto.

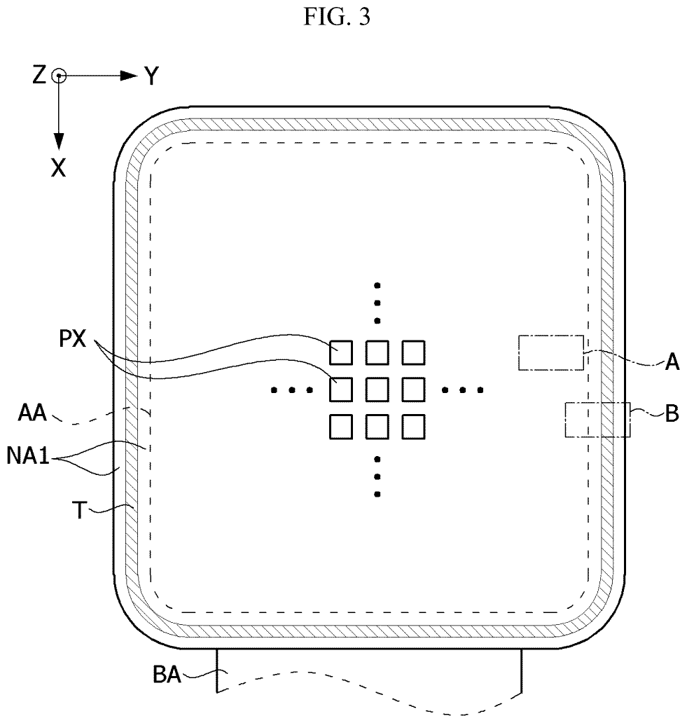

FIG. 3 is an enlarged view showing the display device according to the embodiment of the present disclosure.

Referring to FIG. 3, the first non-display region NA1 may include a region where a trench T is disposed. The region where the trench T is disposed may be formed to have substantially the same shape as the first non-display region NA1. For example, as described below, the first non-display region NA1 may have a rectangular shape whose four corners are formed in a round shape. In this case, the region where the trench T is disposed may have a rectangular shape whose four corners are formed in a round shape. An area of the rectangular shape formed by the outermost perimeter of the region where the trench T is disposed may be smaller than an area of the rectangular shape formed by the outermost perimeter of the first non-display region NA1. The region where the trench T is formed may be disposed to surround the plurality of pixels PX.

In one embodiment, the display region AA may include the region where the trench T is formed. The region where the trench T is formed may be disposed to surround the plurality of pixels PX.

The trench T may be disposed to surround the plurality of pixels PX. At least a portion of the trench T may be disposed between a plurality of light-emitting elements. The plurality of light-emitting elements may be disposed in the display region AA and/or the first non-display region NA1. The trench T may be disposed between the display region AA and the bending region BA. The trench T may be disposed between the display panel 100 and the bending region BA. The trench T may be disposed between at least a portion of the display panel 100 and the bending region BA.

For example, the display region AA of the substrate 110 or the display device 1000 may be configured in various shapes depending on the design of the display device 1000. For example, the display region AA may be configured in a rectangular shape whose four corners are formed in a round shape, but the embodiments of the present disclosure are not limited thereto. For another example, the display region AA may be configured in a rectangular shape whose four corners are formed in a right-angled shape, a circular shape, or the like, but the embodiments of the present disclosure are not limited thereto.

According to the present disclosure, a width of the second non-display region NA2 where a plurality of pad electrodes PE are disposed may be wider than a width of the bending region BA where only a plurality of link lines LL are disposed. Further, a width of the display region AA where the plurality of subpixels are disposed may be wider than the width of the bending region BA where only a plurality of link lines LL are disposed. The drawings show that the width of the bending region BA is narrower than widths of other regions of the substrate 110, but a shape of the substrate 110 including the bending region BA is an example, and the embodiments of the present disclosure are not limited thereto.

FIG. 4 is a plan view showing the display device according to the embodiment of the present disclosure.

Referring to FIG. 4, a plurality of pixel driving circuits PD may be disposed in the display region AA. The plurality of pixel driving circuits PD may be circuits for driving the light-emitting elements of the plurality of subpixels. Each of the plurality of pixel driving circuits PD includes a plurality of transistors including a driving transistor, a storage capacitor, and the like and may control the light-emitting operations of the plurality of light-emitting elements by supplying control signals, power, and a driving current to the light-emitting elements of the plurality of subpixels. For example, the pixel driving circuit PD may include a power line and a signal line for controlling the emission on/off and/or emission time of the light-emitting elements. For example, the plurality of pixel driving circuits PD may be driving drivers manufactured using a metal-oxide-semiconductor field effect transistor (MOSFET) manufacturing process on a semiconductor substrate, but the embodiments of the present disclosure are not limited thereto. The driving driver may include the plurality of pixel driving circuits PD and may drive the plurality of subpixels.

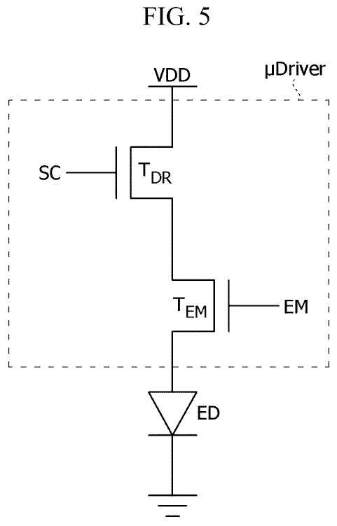

FIG. 5 is a view showing a circuit structure according to the embodiment of the present disclosure.

In FIG. 5, an example in which one light-emitting element ED is connected to a micro driver μDriver is shown, but the present disclosure is not limited thereto. For example, 8 light-emitting elements ED may be connected to one micro driver μDriver. For another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element (μLED).

One micro driver μDriver may include a driving transistor T_{DR} and a light-emitting transistor T_{EM}, but the embodiments of the present disclosure are not limited thereto.

For example, in the driving transistor T_{DR}, a high potential power voltage VDD may be applied to a first electrode, a first electrode of the light-emitting transistor T_{EM} may be connected to a second electrode, and a scan signal SC may be applied to a gate electrode. The scan signal SC applied to the gate electrode of the driving transistor T_{DR} is direct current power, and a fixed reference voltage (Vref) may be applied for each frame, but the embodiments of the present disclosure are not limited thereto.

In the light-emitting transistor T_{EM}, the second electrode of the driving transistor T_{DR} may be connected to the first electrode, the light-emitting element ED may be connected to a second electrode, and an emission signal EM may be applied to a gate electrode. The emission signal EM applied to the gate electrode of the light-emitting transistor T_{EM} may be a pulse width modulation signal which varies for each frame, but the embodiments of the present disclosure are not limited thereto.

A first electrode of the light-emitting element ED may be connected to the second electrode of the light-emitting transistor T_{EM}, and a second electrode of the light-emitting element ED may be connected to the ground. For example, the first electrode of the light-emitting element ED may be an anode electrode and the second electrode of the light-emitting element ED may be a cathode electrode, but the embodiments of the present disclosure are not limited thereto.

The driving transistor T_{DR} and the light-emitting transistor T_{EM} may each be an n-type transistor or a p-type transistor.

In the micro driver μDriver, the driving transistor T_{DR} may be turned on by the scan signal SC applied from a timing controller (T-CON), and the light-emitting transistor T_{EM} may be turned on by the emission signal EM. Accordingly, as a driving current is applied to the light-emitting element ED via the driving transistor T_{DR} and the light-emitting transistor T_{EM} by a high potential power voltage VDD applied to the first electrode of the driving transistor T_{DR}, the light-emitting element ED may emit light.

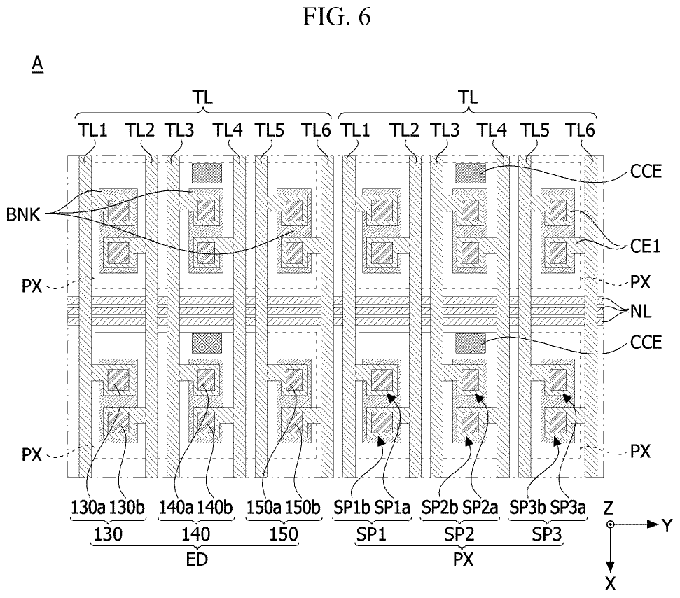

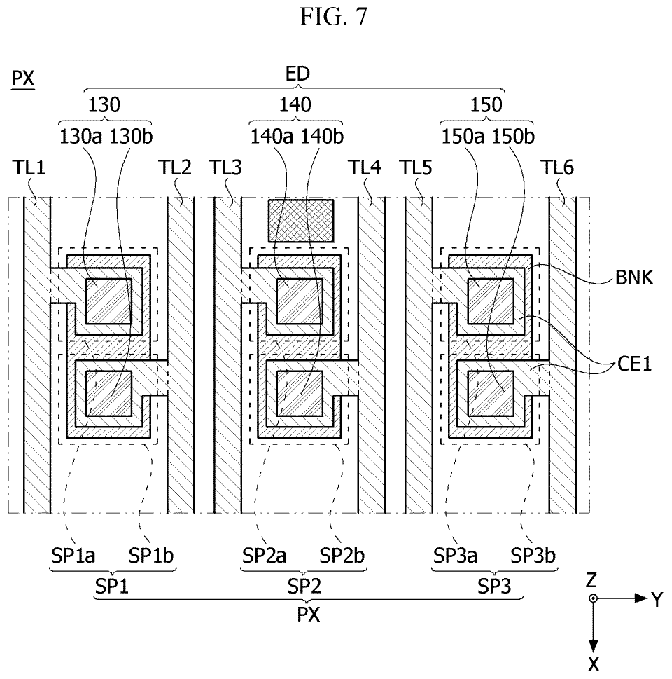

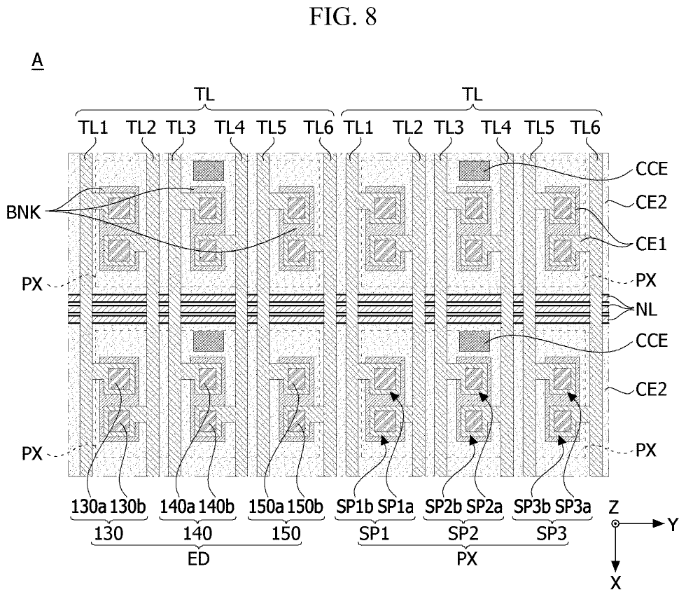

FIG. 6 is an enlarged view of the display region including the plurality of pixels. FIG. 8 is an enlarged view of the display region including the plurality of pixels. FIG. 7 is an enlarged view of the display region including one pixel.

FIG. 7 is a partially enlarged view showing one pixel PX.

In FIGS. 6 and 8, only a plurality of signal lines TL, a plurality of communication lines NL, a plurality of first electrodes CE1, a plurality of banks BNK, and a plurality of light-emitting elements ED are shown, but the embodiments of the present disclosure are not limited thereto. FIG. 8 is an enlarged plan view in which a plurality of second electrodes CE2 are additionally disposed in FIG. 6.

Referring to FIGS. 6 and 8, the plurality of pixels PX composed of a plurality of subpixels may be disposed in the display region AA. Each of the plurality of subpixels includes a light-emitting element ED and may independently emit light. The plurality of subpixels may be disposed in a matrix form, forming a plurality of rows and a plurality of columns, but the embodiments of the present disclosure are not limited thereto.

The plurality of subpixels may include a first subpixel SP1, a second subpixel SP2, and a third subpixel SP3. For example, one of the first subpixel SP1, the second subpixel SP2, and the third subpixel SP3 may be a red subpixel, another may be a green subpixel, and the remaining one may be a blue subpixel. The types of the plurality of subpixels are examples, and the embodiments of the present disclosure are not limited thereto.

Each of the plurality of pixels PX may include one or more first subpixels SP1, one or more second subpixels SP2, and one or more third subpixels SP3. For example, one pixel PX may include a pair of first subpixels SP1, a pair of second subpixels SP2, and a pair of third subpixels SP3. The pair of first subpixels SP1 may be composed of a 1-1 subpixel SP1a and a 1-2 subpixel SP1b. The pair of second subpixels SP2 may be composed of a 2-1 subpixel SP2a and a 2-2 subpixel SP2b. The pair of third subpixels SP3 may be composed of a 3-1 subpixel SP3a and a 3-2 subpixel SP3b. For example, one pixel PX may include the 1-1 subpixel SP1a and the 1-2 subpixel SP1b, the 2-1 subpixel SP2a and the 2-2 subpixel SP2b, and the 3-1 subpixel SP3a and the 3-2 subpixel SP3b, but the embodiments of the present disclosure are not limited thereto.

The plurality of subpixels forming one pixel PX may be arranged in various ways. For example, in one pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. The number and arrangement of the plurality of subpixels forming one pixel PX are examples, and the embodiments of the present disclosure are not limited thereto.

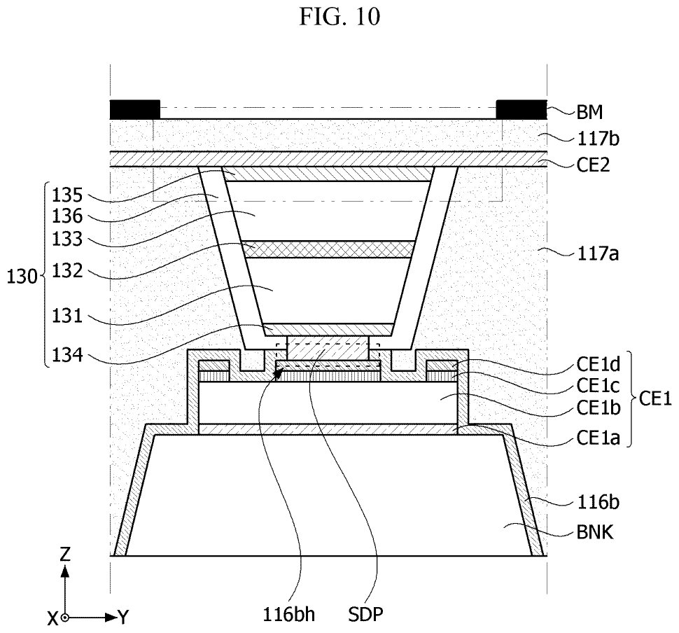

The plurality of signal lines TL may be disposed in regions between the plurality of subpixels. The plurality of signal lines TL may extend between the plurality of subpixels in a column direction. The plurality of signal lines TL may be lines which transmit an anode voltage from the pixel driving circuit PD to the plurality of subpixels. For example, the plurality of signal lines TL may be electrically connected to the plurality of pixel driving circuits PD and the first electrodes CE1 of the plurality of subpixels. The anode voltage output from the pixel driving circuit PD may be transmitted to the first electrodes CE1 of the plurality of subpixels through the plurality of signal lines TL. For example, the first electrode CE1 may be an electrode electrically connected to an anode electrode 134 (see FIG. 10) of the light-emitting element ED. Accordingly, the anode voltage from the signal line TL may be transmitted to the anode electrode 134 of the light-emitting element ED through the first electrode CE1.

Accordingly, instead of forming a plurality of transistors and a plurality of storage capacitors in each of the plurality of subpixels, a structure of the display device 1000 may be simplified using a pixel driving circuit PD in which a plurality of pixel circuits are integrated. Further, as the circuits disposed in each of the plurality of subpixels are integrated into one pixel driving circuit PD, high efficiency and low power driving may be possible. The fact that the circuits disposed in each of the plurality of subpixels SP are integrated into one pixel driving circuit PD means that the plurality of pixel circuits capable of driving the plurality of light-emitting elements ED are included in the pixel driving circuit PD. The plurality of light-emitting elements ED may be driven by one pixel driving circuit PD in which the plurality of pixel circuits are integrated. For example, a 1-1 light-emitting element 130a, a 2-1 light-emitting element 140a, and a 3-1 light-emitting element 150a may be driven by one pixel driving circuit PD in which the plurality of pixel circuits are integrated.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first subpixels SP1, respectively. The third signal line TL3 and the fourth signal line TL4 may be electrically connected to the pair of second subpixels SP2, respectively. The fifth signal line TL5 and the sixth signal line TL6 may be electrically connected to the pair of third subpixels SP3, respectively.

The first signal line TL1 may be disposed on one side of the pair of first subpixels SP1, and the second signal line TL2 may be disposed on the other side of the pair of first subpixels SP1. The first signal line TL1 may be electrically connected to the first electrode CE1 of one of the pair of first subpixels SP1, for example, the 1-1 subpixel SP1a. The second signal line TL2 may be electrically connected to the first electrode CE1 of the other of the pair of first subpixels SP1, for example, the 1-2 subpixel SP1b.

The third signal line TL3 may be disposed on one side of the pair of second subpixels SP2, and the fourth signal line TL4 may be disposed on the other side of the pair of second subpixels SP2. For example, the third signal line TL3 may be disposed adjacent to the second signal line TL2. The third signal line TL3 may be electrically connected to the first electrode CE1 of one of the pair of second subpixels SP2, for example, the 2-1 subpixel SP2a. The fourth signal line TL4 may be electrically connected to the first electrode CE1 of the other of the pair of second subpixels SP2, for example, the 2-2 subpixel SP2b.

The fifth signal line TL5 may be disposed on one side of the pair of third subpixels SP3, and the sixth signal line TL6 may be disposed on the other side of the pair of third subpixels SP3. For example, the fifth signal line TL5 may be disposed adjacent to the fourth signal line TL4. The sixth signal line TL6 may be disposed adjacent to the first signal line TL1 connected to the neighboring pixel PX. The fifth signal line TL5 may be electrically connected to the first electrode CE1 of one of the pair of third subpixels SP3, for example, the 3-1 subpixel SP3a. The sixth signal line TL6 may be electrically connected to the first electrode CE1 of the other of the pair of third subpixels SP3, for example, the 3-2 subpixel SP3b.

The plurality of signal lines TL may be formed of a conductive material. For example, the plurality of signal lines TL may be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present disclosure are not limited thereto. For another example, the plurality of signal lines TL may be formed in a multi-layer structure of conductive materials. For example, the plurality of signal lines TL may be formed in a multi-layer structure of titanium (Ti)/aluminum (Al)/titanium (Ti)/indium tin oxide (ITO), but the embodiments of the present disclosure are not limited thereto.

The plurality of communication lines NL may be disposed in regions between the plurality of pixels PX. The plurality of communication lines NL may be disposed to extend in a row direction in the regions between the plurality of pixels PX. The plurality of communication lines NL may be disposed in regions between the plurality of second electrodes CE2 and may not overlap the plurality of second electrodes CE2. For example, the plurality of communication lines NL may be lines used for short-range communication such as near field communication (NFC). The plurality of communication lines NL may function as antennas. For example, the plurality of communication lines NL may be a plurality of connection lines, and the like, but the embodiments of the present disclosure are not limited thereto.

According to the present disclosure, a bank BNK may be disposed in each of the plurality of subpixels. The plurality of banks BNK may be structures on which the plurality of light-emitting elements ED are seated. The plurality of banks BNK may guide positions of the plurality of light-emitting elements ED in a transfer process of transferring the plurality of light-emitting elements ED to the display device 1000. In the transfer process of the plurality of light-emitting elements ED, the plurality of light-emitting elements ED may be transferred onto the plurality of banks BNK. The plurality of banks BNK may be bank patterns or structures, or the like, but the embodiments of the present disclosure are not limited thereto.

A bank BNK of the first subpixel SP1, a bank BNK of the second subpixel SP2, and a bank BNK of the third subpixel SP3 may disposed spaced apart from each other. The bank BNK of the first subpixel SP1, the bank BNK of the second subpixel SP2, and the bank BNK of the third subpixel SP3 may be configured to be separated. Accordingly, the banks BNK of the first subpixel SP1, the second subpixel SP2, and the third subpixel SP3 to which different types of light-emitting elements ED are transferred may be easily identified.

A bank BNK of the 1-1 subpixel SP1a and a bank BNK of the 1-2 subpixel SP1b may be connected to each other or may be formed to be spaced apart or separated from each other. For example, in consideration of the design of the transfer process requirements or the like, the bank BNK of the 1-1 subpixel SP1a and the bank BNK of the 1-2 subpixel SP1b where the same type of light-emitting elements ED are disposed may be connected to each other or may be spaced apart or separated from each other. Further, a bank BNK of the 2-1 subpixel SP2a and a bank BNK of the 2-2 subpixel SP2b may be connected to each other or may be formed to be spaced apart or separated from each other. A bank BNK of the 3-1 subpixel SP3a and a bank BNK of the 3-2 subpixel SP3b may be connected to each other, or may be formed to be spaced apart or separated from each other. Accordingly, the banks BNK of the pair of first subpixels SP1, the banks BNK of the pair of second subpixels SP2, and the banks BNK of the pair of third subpixels SP3 may be formed in various ways, and the embodiments of the present disclosure are not limited thereto.

For example, the plurality of banks BNK may be formed of an organic insulating material. The plurality of banks BNK may be composed of a single layer or multiple layers of an organic insulating material. For example, the plurality of banks BNK may be composed of a photoresist, a polyimide (PI)-based material, an acryl-based material, or the like, but the embodiments of the present disclosure are not limited thereto.

The first electrode CE1 may be disposed in each of the plurality of subpixels. The first electrode CE1 may be disposed on the bank BNK. The first electrode CE1 may be electrically connected to one of the plurality of signal lines TL. At least a portion of the first electrode CE1 may extend outside the bank BNK and may be electrically connected to the signal line TL most adjacent to the first electrode CE1. For example, a portion of the first electrode CE1 of the 1-1 subpixel SP1a may extend to one side region of the 1-1 subpixel SP1a and may be electrically connected to the first signal line TL1, and a portion of the first electrode CE1 of the 1-2 subpixel SP1b may extend to the other side region of the 1-2 subpixel SP1b and may be electrically connected to the second signal line TL2. A portion of the first electrode CE1 of the 2-1 subpixel SP2a may extend to one side region of the 2-1 subpixel SP2a and may be electrically connected to the third signal line TL3, and a portion of the first electrode CE1 of the 2-2 subpixel SP2b may extend to the other side region of the 2-2 subpixel SP2b and may be electrically connected to the fourth signal line TL4. A portion of the first electrode CE1 of the 3-1 subpixel SP3a may extend to one side region of the 3-1 subpixel SP3a and may be electrically connected to the fifth signal line TL5, and a portion of the first electrode CE1 of the 3-2 subpixel SP3b may extend to the other side region of the 3-2 subpixel SP3b and may be electrically connected to the sixth signal line TL6.

The first electrode CE1 may be electrically connected to the anode electrode 134 of the light-emitting element ED and may transmit the anode voltage from the pixel driving circuit PD to the light-emitting element ED through the signal line TL. Different voltages may be applied to the first electrode CE1 of each of the plurality of subpixels depending on the image to be displayed. For example, different voltages may be applied to the first electrode CE1 of each of the plurality of subpixels. Accordingly, the first electrode CE1 may be a pixel electrode, but the embodiments of the present disclosure are not limited thereto.

The first electrode CE1 may be composed of a conductive material. For example, the first electrode CE1 may be integrally configured with the plurality of signal lines TL. For example, the first electrode CE1 may be composed of the same conductive material as the plurality of signal lines TL, but the embodiments of the present disclosure are not limited thereto. For example, the first electrode CE1 may be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present disclosure are not limited thereto. For another example, the first electrode CE1 may be formed in a multi-layer structure of conductive materials. For example, the plurality of first electrodes CE1 may be formed in a multi-layer structure of titanium (Ti)/aluminum (Al)/titanium (Ti)/indium tin oxide (ITO), but the embodiments of the present disclosure are not limited thereto.

The light-emitting element ED may be disposed in each of the plurality of subpixels. Each of the plurality of light-emitting elements ED may be any one of an LED and a micro LED, but the embodiments of the present disclosure are not limited thereto. The plurality of light-emitting elements ED may be disposed on the banks BNK and the first electrodes CE1. The plurality of light-emitting elements ED may be disposed on the first electrodes CE1 and may be electrically connected to the first electrodes CE1. Accordingly, the light-emitting element ED may emit light by receiving the anode voltage from the pixel driving circuit PD through the signal line TL and the first electrode CE1.

The plurality of light-emitting elements ED may include a first light-emitting element 130 that emits light in a first wavelength band, a second light-emitting element 140 that emits light in a second wavelength band, and a third light-emitting element 150 that emits light in a third wavelength band. The first light-emitting element 130 may be disposed in the first subpixel SP1. The second light-emitting element 140 may be disposed in the second subpixel SP2. The third light-emitting element 150 may be disposed in the third subpixel SP3. For example, one of the first light-emitting element 130, the second light-emitting element 140, and the third light-emitting element 150 may be a red light-emitting element, another may be a green light-emitting element, and the remaining one may be a blue light-emitting element, but the embodiments of the present disclosure are not limited thereto. A size of at least one of the first light-emitting element 130, the second light-emitting element 140, and the third light-emitting element 150 may be different from sizes of the other light-emitting elements. The size of the first light-emitting element 130 may be larger than each of the sizes of the second light-emitting element 140 and the third light-emitting element 150. The sizes of the second light-emitting element 140 and the third light-emitting element 150 may be the same. The first light-emitting element 130, the second light-emitting element 140, and the third light-emitting element 150 may all be inorganic light-emitting elements. For example, various colors of light including white light may be implemented by combining red light, green light, and blue light emitted from the plurality of light-emitting elements ED. The types of the plurality of light-emitting elements ED are examples, and the embodiments of the present disclosure are not limited thereto.

The first light-emitting element 130 may include a 1-1 light-emitting element 130a disposed in the 1-1 subpixel SP1a and a 1-2 light-emitting element 130b disposed in the 1-2 subpixel SP1b. The second light-emitting element 140 may include a 2-1 light-emitting element 140a disposed in the 2-1 subpixel SP2a and a 2-2 light-emitting element 140b disposed in the 2-2 subpixel SP2b. The third light-emitting element 150 may include a 3-1 light-emitting element 150a disposed in the 3-1 subpixel SP3a and a 3-2 light-emitting element 150b disposed in the 3-2 subpixel SP3b.

Referring to FIG. 8, a second electrode CE2 may be disposed in each of the plurality of subpixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to a cathode electrode 135 (see FIG. 10) of the light-emitting element ED to transmit a cathode voltage from the pixel driving circuit PD to the light-emitting element ED. The same cathode voltage may be applied to the second electrode CE2 of each of the plurality of subpixels. For example, the same voltage may be applied to the second electrode CE2 of each of the plurality of subpixels and the cathode electrode 135 of the light-emitting element ED. Accordingly, the second electrode CE2 may be a common electrode, but the embodiments of the present disclosure are not limited thereto.

At least some of the plurality of subpixels may share the second electrode CE2. At least some of the second electrodes CE2 of each of the plurality of subpixels may be electrically connected to each other. As the same voltage is applied to the second electrodes CE2, the second electrodes CE2 of at least some of the subpixels may be shared and used. For example, the second electrodes CE2 of at least some pixels PX of the plurality of pixels PX disposed in the same row may be connected to each other. For example, one second electrode CE2 may be disposed in the plurality of pixels PX. One second electrode CE2 may be disposed for every n subpixels.

For example, some of the second electrodes CE2 of each of the plurality of subpixels may be disposed to be spaced apart or separated from each other. For example, the second electrode CE2 connected to pixels PX in an nth row and the second electrode CE2 connected to pixels PX in an n+1th row may be disposed to be spaced apart or separated from each other. For example, the plurality of second electrodes CE2 may be disposed spaced apart from each other with the plurality of communication lines NL extending in the row direction therebetween. Accordingly, the number of subpixels may be greater than the number of second electrodes CE2. For another example, all the second electrodes CE2 of the plurality of subpixels may be connected to each other and thus only one second electrode CE2 may be disposed on the substrate 110, but the embodiments of the present disclosure are not limited thereto.

The plurality of second electrodes CE2 may be composed of a transparent conductive material, but the embodiments of the present disclosure are not limited thereto. The plurality of second electrodes CE2 may be formed of a transparent conductive material so that light emitted from the light-emitting element ED may be directed toward an upper portion of the second electrodes CE2. For example, the second electrode CE2 may be composed of a transparent conductive material such as indium tin oxide (ITO), indium zinc oxide (IZO), indium gallium zinc oxide (IGZO), or the like, but the embodiments of the present disclosure are not limited thereto.

The plurality of contact electrodes CCE may be disposed on the substrate 110. For example, the plurality of contact electrodes CCE may be disposed spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD to the second electrodes CE2.

For example, when micro LEDs are used as the light-emitting elements ED, the display device 1000 may be manufactured by forming a plurality of micro LEDs on a wafer and transferring the micro LEDs to the substrate 110 of the display device 1000. In the process of transferring the plurality of light-emitting elements ED having a fine size from the wafer to the substrate 110, various defects may occur. For example, in some subpixels, a non-transfer defect in which the light-emitting element ED is not transferred may occur, and in other subpixels, a defect in which the light-emitting element ED is transferred to an incorrect position due to an alignment error may occur. Further, although the transfer process is normally performed, the transferred light-emitting element ED itself may be defective. Accordingly, in consideration of defects during the transfer process of the plurality of light-emitting elements ED, the plurality of light-emitting elements ED of the same type may be transferred to one subpixel. A lighting test may be performed on the plurality of light-emitting elements ED, and ultimately, only one light-emitting element ED that is determined to be normal may be used.

For example, the 1-1 light-emitting element 130a and the 1-2 light-emitting element 130b may be transferred together to one pixel PX and inspected for defects. When both the 1-1 light-emitting element 130a and the 1-2 light-emitting element 130b are determined to be normal, only the 1-1 light-emitting element 130a may be used and the 1-2 light-emitting element 130b may not be used. For another example, when only the 1-2 light-emitting element 130b is determined to be normal among the 1-1 light-emitting element 130a and the 1-2 light-emitting element 130b, the 1-1 light-emitting element 130a may not be used and only the 1-2 light-emitting element 130b may be used. Accordingly, even when the plurality of light-emitting elements ED of the same type are transferred to one pixel PX, ultimately, only one light-emitting element ED may be used.

Accordingly, one of the pair of light-emitting elements ED may be a main (or primary) light-emitting element ED and the other may be a redundancy light-emitting element ED. The redundancy light-emitting element ED may be a spare light-emitting element ED transferred to prepare for a defective main light-emitting element ED. When the main light-emitting element ED is defective, the redundancy light-emitting element ED may be used as a replacement. Accordingly, the deterioration of display quality due to the defects of the main light-emitting element ED and the redundancy light-emitting element ED may be minimized by transferring the main light-emitting element ED and the redundancy light-emitting element ED together to one pixel PX.

For example, the 1-1 light-emitting element 130a, the 2-1 light-emitting element 140a, and the 3-1 light-emitting element 150a transferred to one pixel PX may be used as the main light-emitting elements ED, and the 1-2 light-emitting element 130b, the 2-2 light-emitting element 140b, and the 3-2 light-emitting element 150b may be used as the redundancy light-emitting elements ED.

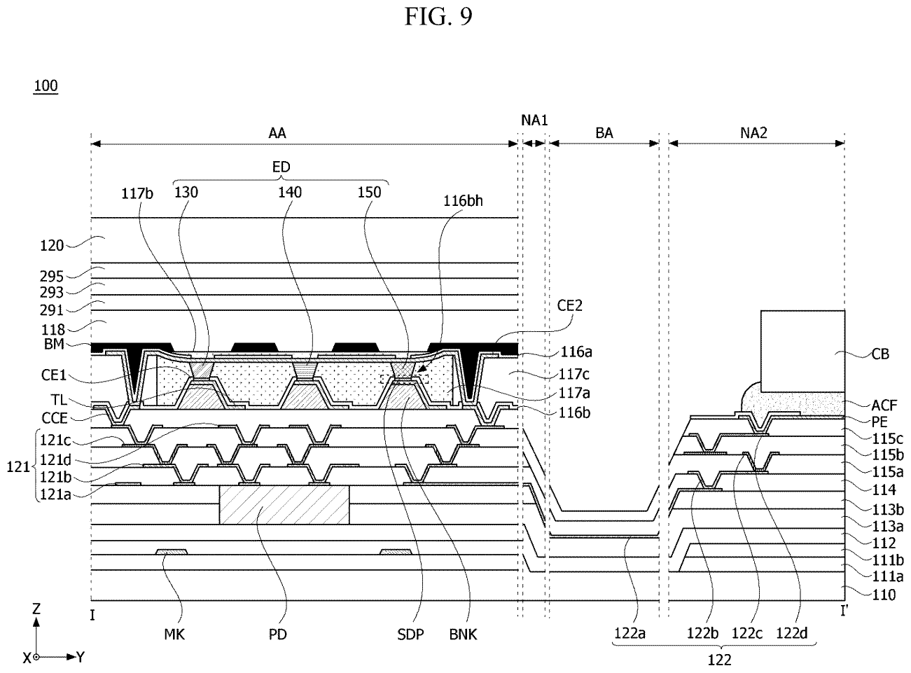

FIG. 9 is a cross-sectional view of the display device according to the embodiment of the present disclosure taken along line I-I′ in FIG. 4. FIG. 10 is a cross-sectional view showing a subpixel including the light-emitting element disposed in the display region.

FIG. 9 is a cross-sectional view of the display region AA, the first non-display region NA1, the bending region BA, and the second non-display region NA2.

Referring to FIG. 9, a first buffer layer 111a and a second buffer layer 111b may be disposed on the remaining region of the substrate 110 excluding the bending region BA.

The first buffer layer 111a and the second buffer layer 111b may be disposed in the display region AA, the first non-display region NA1, and the second non-display region NA2. The first buffer layer 111a and the second buffer layer 111b may reduce the penetration of moisture or impurities through the substrate 110. The first buffer layer 111a and the second buffer layer 111b may be formed of an inorganic insulating material. For example, the first buffer layer 111a and the second buffer layer 111b may be composed of a single layer or multiple layers of silicon oxide (SiOₓ) or silicon nitride (SiNₓ), but the embodiments of the present disclosure are not limited thereto.

For example, portions of the first buffer layer 111a and the second buffer layer 111b in the bending region BA may be removed. An upper surface of the substrate 110 located in the bending region BA may be exposed from the first buffer layer 111a and the second buffer layer 111b. Cracks in the first buffer layer 111a and the second buffer layer 111b which may occur during bending may be minimized by removing the first buffer layer 111a and the second buffer layer 111b formed of an inorganic insulating material from the bending region BA.

A plurality of alignment keys MK may be disposed between the first buffer layer 111a and the second buffer layer 111b. The plurality of alignment keys MK may be configured to identify a position of the pixel driving circuit PD during the manufacturing process of the display device 1000. For example, the plurality of alignment keys MK may be configured to align the position of the pixel driving circuit PD transferred onto an adhesive layer 112. For another example, the plurality of alignment keys MK may be omitted.

The adhesive layer 112 may be disposed on the second buffer layer 111b. The adhesive layer 112 may be disposed in the display region AA, the first non-display region NA1, the bending region BA, and the second non-display region NA2. For another example, at least a portion of the adhesive layer 112 may be removed in the non-display region NA including the bending region BA. For example, the adhesive layer 112 may be formed of any one of an adhesive polymer, an epoxy resin, a UV-curable resin, a polyimide-based material, an acrylate-based material, a urethane-based material, and polydimethylsiloxane (PDMS), but the embodiments of the present disclosure are not limited thereto.

The pixel driving circuit PD may be disposed on the adhesive layer 112 in the display region AA. When the pixel driving circuit PD is implemented as a driving driver, the driving driver may be mounted on the adhesive layer 112 by a transfer process, but the embodiments of the present disclosure are not limited thereto.

A first protective layer 113a and a second protective layer 113b may be disposed on the adhesive layer 112 and the pixel driving circuit PD. The first protective layer 113a and the second protective layer 113b may be disposed to surround the side surfaces of the pixel driving circuit PD, but the embodiments of the present disclosure are not limited thereto. For example, the second protective layer 113b may be disposed to cover at least a portion of an upper surface of the pixel driving circuit PD. For example, at least one of the first protective layer 113a and the second protective layer 113b disposed in the bending region BA may be omitted. For example, the first protective layer 113a may be entirely disposed in the display region AA and the non-display region NA, and the second protective layer 113b may be partially disposed in the display region AA, the first non-display region NA1, and the second non-display region NA2. For example, a portion of the second protective layer 113b in the bending region BA may be removed. However, the embodiments of the present disclosure are not limited thereto.

The first protective layer 113a and the second protective layer 113b may be composed of an organic insulating material, but the embodiments of the present disclosure are not limited thereto. For example, the first protective layer 113a and the second protective layer 113b may be composed of a photoresist, a polyimide (PI)-based material, a photo acrylic-based material, or the like, but the embodiments of the present disclosure are not limited thereto. For example, the first protective layer 113a and the second protective layer 113b may be overcoating layers or insulating layers, but the embodiments of the present disclosure are not limited thereto.

According to the present disclosure, a plurality of first connection lines 121 may be disposed on the second protective layer 113b in the display region AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present disclosure are not limited thereto.

For example, a plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit a voltage output from the pixel driving circuit PD to the first electrode CEL or the second electrode CE2.

For example, a third protective layer 114 may be disposed on the second protective layer 113b. The third protective layer 114 may be entirely disposed in the display region AA and the non-display region NA. The third protective layer 114 may cover side surfaces of the second protective layer 113b and an upper surface of the first protective layer 113a in the bending region BA. The third protective layer 114 may be composed of an organic insulating material. For example, the third protective layer 114 may be composed of a photoresist, a polyimide (PI)-based material, a photo acrylic-based material, or the like, but the embodiments of the present disclosure are not limited thereto. For example, the first protective layer 113a, the second protective layer 113b, and the third protective layer 114 may be composed of the same material. However, the embodiments of the present disclosure are not limited thereto.

A plurality of 1-2 connection lines 121b may be disposed on the third protective layer 114. The plurality of 1-2 connection lines 121b may be connected to or directly connected to the pixel driving circuit PD. For example, some of the 1-2 connection lines 121b may be directly connected to the pixel driving circuit PD through contact holes of the third protective layer 114. Other 1-2 connection lines 121b may be electrically connected to the 1-1 connection line 121a through the contact holes of the third protective layer 114. However, the embodiments of the present disclosure are not limited thereto. The voltage output from the pixel driving circuit PD may be transmitted to the first electrode CE1 or the second electrode CE2 through the plurality of 1-2 connection lines 121b and other connection lines.

A first insulating layer 115a may be disposed on the plurality of 1-2 connection lines 121b. The first insulating layer 115a may be entirely disposed in the display region AA and the non-display region NA, but the embodiments of the present disclosure are not limited thereto. The first insulating layer 115a may be composed of an organic insulating material, but the embodiments of the present disclosure are not limited thereto. For example, first insulating layer 115a may be composed of a photoresist, a polyimide (PI)-based material, a photo acrylic-based material, or the like, but the embodiments of the present disclosure are not limited thereto.

A plurality of 1-3 connection lines 121c may be disposed on the first insulating layer 115a. The plurality of 1-3 connection lines 121c may be electrically connected to the plurality of 1-2 connection lines 121b. For example, the 1-3 connection lines 121c may be electrically connected to the 1-2 connection lines 121b through contact holes of the first insulating layer 115a.

A second insulating layer 115b may be disposed on the plurality of 1-3 connection lines 121c. The second insulating layer 115b may be disposed in the remaining region excluding the bending region BA, but the embodiments of the present disclosure are not limited thereto. The second insulating layer 115b may be disposed in the display region AA, the first non-display region NA1, and the second non-display region NA2, but the embodiments of the present disclosure are not limited thereto. For example, a portion of the second insulating layer 115b disposed in the bending region BA may be removed. The second insulating layer 115b may be composed of an organic insulating material, but the embodiments of the present disclosure are not limited thereto. For example, second insulating layer 115b may be composed of a photoresist, a polyimide (PI)-based material, a photo acrylic-based material, or the like, but the embodiments of the present disclosure are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the 1-4 connection lines 121d may be electrically connected to the 1-3 connection lines 121c through contact holes of the second insulating layer 115b.

According to the present disclosure, a plurality of second connection lines 122 may be disposed on the second protective layer 113b in the non-display region NA. The plurality of second connection lines 122 may be lines for transmitting signals transmitted from the flexible circuit board (or flexible film) CB and the printed circuit board 160 (see in FIG. 1) to the pad portion PAD to the pixel driving circuit PD of the display region AA. For example, the plurality of second connection lines 122 may be electrically connected to the plurality of pad electrodes PE to receive signals from the flexible circuit board (or flexible film) CB and the printed circuit board 160.

For example, the plurality of second connection lines 122 may extend from the pad portion PAD toward the display region AA and transmit the signals to lines in the display region AA. In this case, the plurality of second connection lines 122 may function as link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-display region NA2 to the bending region BA and the first non-display region NA1. The plurality of 2-1 connection lines 122a may transmit signals transmitted from the flexible circuit board (or flexible film) CB and the printed circuit board to the pad portion PAD to the pixel driving circuit PD of the display region AA.

A plurality of 2-2 connection lines 122b may be disposed on the third protective layer 114. The plurality of 2-2 connection lines 122b may be disposed in the second non-display region NA2. The 2-2 connection lines 122b may be electrically connected to the 2-1 connection lines 122a through contact holes of the third protective layer 114. Accordingly, the signals from the flexible circuit board (or flexible film) CB and the printed circuit board may be transmitted to the 2-1 connection lines 122a through the 2-2 connection lines 122b.

The 2-3 connection line 122c may be disposed on the first insulating layer 115a. The 2-3 connection line 122c may be disposed in the second non-display region NA2. The 2-3 connection line 122c may be electrically connected to the 2-2 connection lines 122b through a contact hole of the first insulating layer 115a. Accordingly, the signals from the flexible circuit board (or flexible film) CB and the printed circuit board may be transmitted to the 2-1 connection lines 122a through the 2-3 connection line 122c and the 2-2 connection lines 122b.

The 2-4 connection line 122d may be disposed on the second insulating layer 115b. The 2-4 connection line 122d may be disposed in the second non-display region NA2. The 2-4 connection line 122d may be electrically connected to the 2-3 connection line 122c through a contact hole of the second insulating layer 115b. Accordingly, the signals from the flexible circuit board (or flexible film) CB and the printed circuit board may be transmitted to the 2-1 connection lines 122a through the 2-4 connection line 122d, the 2-3 connection line 122c, and the 2-2 connection lines 122b.

The plurality of first connection lines 121 and the plurality of second connection lines 122 may be formed of a conductive material having excellent flexibility or any one of various conductive materials used in the display region AA. For example, the second connection line 122 partially disposed in the bending region BA may be composed of a conductive material having excellent flexibility such as gold (Au), silver (Ag), aluminum (Al), or the like, but the embodiments of the present disclosure are not limited thereto. For another example, the plurality of first connection lines 121 and the plurality of second connection lines 122 may be composed of molybdenum (Mo), chromium (Cr), titanium (Ti), nickel (Ni), neodymium (Nd), copper (Cu), an alloy of silver (Ag) and magnesium (Mg), alloys thereof, or the like, but the embodiments of the present disclosure are not limited thereto.

A third insulating layer 115c may be disposed on the plurality of first connection lines 121 and the plurality of second connection lines 122. The third insulating layer 115c may be disposed in the remaining region excluding the bending region BA, but the embodiments of the present disclosure are not limited thereto. The third insulating layer 115c may be disposed in the display region AA, the first non-display region NA1, and the second non-display region NA2. A portion of the third insulating layer 115c disposed in the bending region BA may be removed. The third insulating layer 115c may be composed of an organic insulating material, but the embodiments of the present disclosure are not limited thereto. For example, the third insulating layer 115c may be composed of a photoresist, a polyimide (PI)-based material, a photo acrylic-based material, or the like, but the embodiments of the present disclosure are not limited thereto.

The plurality of banks BNK may be disposed on the third insulating layer 115c in the display region AA. The plurality of banks BNK may be disposed to overlap the plurality of subpixels, respectively. One or more light-emitting elements ED of the same type may be disposed on each of the plurality of banks BNK.

The plurality of signal lines TL may be disposed on the third insulating layer 115c in the display region AA. The plurality of signal lines TL may be disposed in regions between the plurality of banks BNK. For example, the plurality of signal lines TL may be disposed adjacent to any one of the plurality of banks BNK.

The plurality of contact electrodes CCE may be disposed on the third insulating layer 115c in the display region AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from adjacent signal line TL toward an upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

A black matrix BM may be disposed on the second electrode CE2, a first optical layer 117a, a third optical layer 117c, and a second optical layer 117b in the display region AA. For example, the black matrix BM may fill a contact hole of the third optical layer 117c. The black matrix BM is configured to cover the display region AA, and thus may reduce the color mixing of light of the plurality of subpixels and external light reflection. For example, the black matrix BM is also disposed in the contact hole by which the second electrode CE2 and the contact electrode CCE are connected, and thus may prevent light leakage between the plurality of neighboring subpixels.

For example, the black matrix BM may be composed of an opaque material, but the embodiments of the present disclosure are not limited thereto. For example, the black matrix BM may be an organic insulating material to which a black pigment or black dye is added, but the embodiments of the present disclosure are not limited thereto.

A cover layer 118 may be disposed on the black matrix BM in the display region AA. The cover layer 118 may protect the configuration under the cover layer 118. For example, the cover layer 118 may be composed of an organic insulating material, but the embodiments of the present disclosure are not limited thereto. For example, the cover layer 118 may be composed of a photoresist, a polyimide (PI)-based material, a photo acrylic-based material, or the like, but the embodiments of the present disclosure are not limited thereto. For example, the cover layer 118 may be an overcoating layer or an insulating layer, but the embodiments of the present disclosure are not limited thereto.

The polarization layer 293 may be disposed on the cover layer 118 via a first adhesive layer 291. The cover member 120 may be disposed on the polarization layer 293 via the second adhesive layer 295. For example, the first adhesive layer 291 and the second adhesive layer 295 may include an optically clear adhesive (OCA), an optically clear resin (OCR), a pressure sensitive adhesive (PSA), or the like, but the embodiments of the present disclosure are not limited thereto.

According to the present disclosure, the plurality of pad electrodes PE may be disposed on the third insulating layer 115c in the second non-display region NA2. For example, at least portions of the plurality of pad electrodes PE may be exposed from a second inorganic film layer 116b. For example, the plurality of pad electrodes PE may be electrically connected to the 2-4 connection line 122d through contact holes of the third insulating layer 115c.

An adhesive layer ACF may be disposed on the plurality of pad electrodes PE. The adhesive layer ACF may be an adhesive layer in which conductive balls are dispersed in an insulating material, but the embodiments of the present disclosure are not limited thereto. When heat or pressure is applied to the adhesive layer ACF, since the conductive balls may be electrically connected at a portion to which the heat or pressure is applied, the adhesive layer ACF may have conductive properties. The flexible circuit board (or flexible film) CB may be attached or bonded to the plurality of pad electrodes PE by disposing the adhesive layer ACF between the plurality of pad electrodes PE and the flexible circuit board (or flexible film) CB. For example, the adhesive layer ACF may be an anisotropic conductive film (ACF), but the embodiments of the present disclosure are not limited thereto.

The flexible circuit board (or flexible film) CB may be disposed on the adhesive layer ACF. The flexible circuit board (or flexible film) CB may be electrically connected to the plurality of pad electrodes PE through the adhesive layer ACF. Accordingly, the signals output from the flexible circuit board (or flexible film) CB and the printed circuit board may be transmitted to the pixel driving circuit PD of the display region AA through the plurality of pad electrodes PE, the 2-4 connection line 122d, the 2-3 connection line 122c, the 2-2 connection line 122b, and the 2-1 connection line 122a.

FIG. 10 is a cross-sectional view showing the subpixel including the light-emitting element disposed in the display region AA.

Referring to FIG. 10, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be composed of titanium (Ti), molybdenum (Mo), aluminum (Al), or indium tin oxide (ITO), but the embodiments of the present disclosure are not limited thereto.

According to the present disclosure, some conductive layers having excellent reflection efficiency among the plurality of conductive layers constituting the first electrode CE1 may be configured as alignment keys for aligning the light-emitting elements ED and/or reflective plates. For example, the second conductive layer CE1b among the plurality of conductive layers of the first electrode CE1 may include a reflective material. For example, the second conductive layer CE1b may include aluminum (Al), but the embodiments of the present disclosure are not limited thereto. Accordingly, the second conductive layer CE1b may be configured as a reflective plate. Further, identification in the manufacturing process may be facilitated due to the high reflective efficiency of the second conductive layer CE1b, and thus a position or transfer position of the light-emitting element ED may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, portions of the third conductive layer CE1c and fourth conductive layer CE1d disposed on the bank BNK may be removed or etched to expose an upper surface of the second conductive layer CE1b. For example, in the third conductive layer CE1c and the fourth conductive layer CE1d, center portions and edge portions where a solder pattern SDP is disposed may be left, and the remaining portion may be removed. For example, the edge portion of each of the third conductive layer CE1c made of titanium (Ti) and the fourth conductive layer CE1d made of indium tin oxide (ITO) may not be etched. Accordingly, it is possible to prevent other conductive layers of the first electrode CE1 from being corroded by a tetramethylammonium hydroxide (TMAH) solution used in a mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) having excellent adhesion to the solder pattern SDP and having corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the embodiments of the present disclosure are not limited thereto.

According to the present disclosure, the signal line TL, the contact electrode CCE, and the pad electrode PE disposed on the same layer as the first electrode CE1 may be composed of multiple layers of a conductive material, but the embodiments of the present disclosure are not limited thereto. For example, the signal line TL, the contact electrode CCE, and the pad electrode PE may be formed of multiple layers of indium tin oxide (ITO)/titanium (Ti)/aluminum (Al)/titanium (Ti), but the embodiments of the present disclosure are not limited thereto.

According to the present disclosure, the solder pattern SDP may be disposed on the first electrode CE1 in each of the plurality of subpixels. The solder pattern SDP may bond the light-emitting element ED to the first electrode CE1. The first electrode CE1 and the light-emitting element ED may be electrically connected by eutectic bonding using the solder pattern SDP, but the embodiments of the present disclosure are not limited thereto. For example, when the solder pattern SDP is composed of indium (In) and the anode electrode 134 of the light-emitting element ED is composed of gold (Au), the solder pattern SDP and the anode electrode 134 may be bonded by applying heat and pressure during the transfer process of the light-emitting element ED. The light-emitting element ED may be bonded to the solder pattern SDP and the first electrode CE1 by eutectic bonding without a separate adhesive. For example, the solder pattern SDP may be composed of indium (In), tin (Sn), or an alloy thereof, but the embodiments of the present disclosure are not limited thereto. For example, the solder pattern SDP may be a bonding pad or a joining pad, but the embodiments of the present disclosure are not limited thereto.

According to the present disclosure, the second inorganic film layer 116b may be disposed on the plurality of signal lines TL, the plurality of first electrodes CE1, the plurality of contact electrodes CCE, and the third insulating layer 115c. For example, the second inorganic film layer 116b may be disposed in the display region AA, the first non-display region NA1, and the second non-display region NA2. A portion of the second inorganic film layer 116b disposed in the bending region BA may be removed. A portion of the second inorganic film layer 116b covering the plurality of pad electrodes PE in the second non-display region NA2 may be removed. Since the second inorganic film layer 116b is disposed to cover the remaining region excluding regions where the bending region BA, the plurality of pad electrodes PE, and the solder pattern SDP are disposed, the penetration of moisture or impurities into the light-emitting element ED may be reduced. For example, the second inorganic film layer 116b may be composed of a single layer or multiple layers of silicon oxide (SiOₓ) or silicon nitride (SiNₓ), but the embodiments of the present disclosure are not limited thereto. For example, the second inorganic film layer 116b may be a protective layer or an insulating layer, but the embodiments of the present disclosure are not limited thereto. Further, the second inorganic film layer 116b may include a hole 116bh which exposes the solder pattern SDP.

The light-emitting element ED may be disposed on the solder pattern SDP in each of the plurality of subpixels. The first light-emitting element 130 may be disposed in the first subpixel SP1. The second light-emitting element 140 may be disposed in the second subpixel SP2. The third light-emitting element 150 may be disposed in the third subpixel SP3.

The light-emitting element ED may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like, but the embodiments of the present disclosure are not limited thereto.

The first optical layer 117a surrounding the plurality of light-emitting elements ED may be disposed in the display region AA. For example, the first optical layer 117a may be disposed to cover the plurality of light-emitting elements ED and the plurality of banks BNK in regions of the plurality of subpixels. For example, the first optical layer 117a may cover the bank BNK, a portion of the second inorganic film layer 116b, and a space between the plurality of light-emitting elements ED. The first optical layer 117a may be disposed between the plurality of light-emitting elements ED included in one pixel PX and between the plurality of banks BNK or may cover spaces between the plurality of light-emitting elements ED and between the plurality of banks BNK. For example, the first optical layers 117a may extend in the first direction X and may be disposed spaced apart from each other in the second direction Y. For example, the first optical layer 117a may be disposed between the second inorganic film layer 116b and the second electrode CE2 to surround side portions of the light-emitting element ED and the bank BNK, but the embodiments of the present disclosure are not limited thereto. For example, the first optical layer 117a may be a diffusion layer, a sidewall diffusion layer, or the like, but the embodiments of the present disclosure are not limited thereto.

The first optical layer 117a may include an organic insulating material in which fine particles are dispersed, but the embodiments of the present disclosure are not limited thereto. For example, the first optical layer 117a may be composed of siloxane in which fine metal particles such as titanium dioxide (TiO₂) particles are dispersed, but the embodiments of the present disclosure are not limited thereto. Light from the plurality of light-emitting elements ED may be scattered by the fine particles dispersed in the first optical layer 117a and emitted to the outside of the display device 1000. Accordingly, the first optical layer 117a may enhance the extraction efficiency of the light emitted from the plurality of light-emitting elements ED.

For example, the first optical layer 117a may be disposed in each of the plurality of pixels PX, or may be disposed together in some of the pixels PX disposed in the same row, but the embodiments of the present disclosure are not limited thereto. For example, the first optical layer 117a may be disposed in each of the plurality of pixels PX, or the plurality of pixels PX may share one first optical layer 117a. For another example, each of the plurality of subpixels may separately include the first optical layer 117a, but the embodiments of the present disclosure are not limited thereto.

According to the present disclosure, the third optical layer 117c may be disposed on the second inorganic film layer 116b in the display region AA. For example, the third optical layer 117c may be disposed to surround the first optical layer 117a. For example, the third optical layer 117c may be in contact with a side surface of the first optical layer 117a. For example, the third optical layer 117c may be disposed in the region between the plurality of pixels PX. However, the embodiments of the present disclosure are not limited thereto. For example, the third optical layer 117c may be a diffusion layer, a diffusion layer window, a window diffusion layer, or the like, but the embodiments of the present disclosure are not limited thereto.

The third optical layer 117c may be composed of an organic insulating material, but the embodiments of the present disclosure are not limited thereto. The third optical layer 117c may be composed of the same material as the first optical layer 117a, but the embodiments of the present disclosure are not limited thereto. For example, the first optical layer 117a may include fine particles, and the third optical layer 117c may not include fine particles. For example, the third optical layer 117c may be formed of siloxane, but the embodiments of the present disclosure are not limited thereto.

For example, a thickness of the first optical layer 117a may be less than a thickness of the third optical layer 117c, but the embodiments of the present disclosure are not limited thereto. Accordingly, when viewed in a plan view, a region where the first optical layer 117a is disposed may include a concave portion recessed inward from an upper surface of the third optical layer 117c.

According to the present disclosure, the second electrode CE2 may be disposed on the first optical layer 117a and the third optical layer 117c. For example, the second electrode CE2 may be electrically connected to the plurality of contact electrodes CCE through contact holes of the third optical layer 117c. For example, the second electrode CE2 may be disposed on the plurality of light-emitting elements ED. For example, the second electrode CE2 may include a transparent conductive oxide such as indium tin oxide (ITO), indium zinc oxide (IZO), or the like, but the embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover an outer flat surface of the first optical layer 117a.

The second electrode CE2 may continuously extend in the first direction X of the substrate 110. Accordingly, the second electrode CE2 may be connected to the plurality of pixels PX arranged in the first direction X of the substrate 110, in common. For example, the second electrode CE2 may be connected to the plurality of pixels PX in common.

According to the present disclosure, the second electrode CE2 may continuously extend on the first optical layer 117a, the third optical layer 117c, and the light-emitting element ED. The region where the first optical layer 117a is disposed may include the concave portion recessed inward from the upper surface of the third optical layer 117c. Accordingly, a first portion of the second electrode CE2 disposed on the first optical layer 117a is disposed along the concave portion, and thus may be disposed at a lower position than a second portion of the second electrode CE2 disposed on the third optical layer 117c.

The second optical layer 117b may be disposed on the second electrode CE2. The second optical layer 117b may be disposed to overlap the plurality of light-emitting elements ED and the first optical layer 117a. Since the second optical layer 117b is disposed on the second electrode CE2 and the plurality of light-emitting elements ED, the stain (mura) which may occur over some of the plurality of light-emitting elements ED may be improved. For example, when the plurality of light-emitting elements ED are transferred onto the substrate 110 of the display device 1000, a region where intervals between the plurality of light-emitting elements ED are not uniform may occur due to a process deviation or the like. When the intervals between the plurality of light-emitting elements ED are not uniform, a light-emitting region of each of the plurality of light-emitting elements ED may be disposed non-uniformly, and the stain (mura) may be visible to the user. Accordingly, since the second optical layer 117b is configured to uniformly diffuse light over the plurality of light-emitting elements ED, it is possible to reduce the light emitted from some of the light-emitting elements ED from being visible to the user as stain (mura). Accordingly, since the light emitted from the plurality of light-emitting elements ED is uniformly diffused by the second optical layer 117b and extracted to the outside of the display device 1000, the brightness uniformity of the display device 1000 may be enhanced.

The second optical layer 117b may be composed of an organic insulating material in which fine particles are dispersed, but the embodiments of the present disclosure are not limited thereto. For example, the second optical layer 117b may be composed of siloxane in which fine metal particles such as titanium dioxide (TiO₂) particles are dispersed, but the embodiments of the present disclosure are not limited thereto. For example, the second optical layer 117b may be composed of the same material as the first optical layer 117a, but the embodiments of the present disclosure are not limited thereto. For example, the second optical layer 117b may be a diffusion layer or an upper surface diffusion layer, but the embodiments of the present disclosure are not limited thereto.

According to the present disclosure, light from the plurality of light-emitting elements ED may be scattered by the fine particles dispersed in the second optical layer 117b and emitted to the outside of the display device 1000. The second optical layer 117b may uniformly mix the light emitted from the plurality of light-emitting elements ED to further enhance the brightness uniformity of the display device 1000. Further, the light extraction efficiency of the display device 1000 may be enhanced by the light scattered from the plurality of fine particles, and accordingly, the display device 1000 may be driven at low power.

According to the present disclosure, a first inorganic film layer 116a may be disposed on the first optical layer 117a. Alternatively, the first inorganic film layer 116a may be disposed on the second optical layer 117b. Alternatively, the first inorganic film layer 116a may be disposed on the third optical layer 117c. For example, the first inorganic film layer 116a may be disposed in the display region AA and the first non-display region NA1. Since the first inorganic film layer 116a is disposed to cover the first optical layer 117a, the second optical layer 117b, or the third optical layer 117c disposed in the display region AA and the first non-display region NA1, the penetration of moisture or impurities into the first optical layer 117a, the second optical layer 117b, or the third optical layer 117c may be reduced. For example, the first inorganic film layer 116a may be composed of a single or multiple layers of silicon oxide (SiOₓ) or silicon nitride (SiNₓ), but the embodiments of the present disclosure are not limited thereto. For example, the first inorganic film layer 116a may be a protective layer or an insulating layer, but the embodiments of the present disclosure are not limited thereto.

The first light-emitting element 130 may include the anode electrode 134, a first semiconductor layer 131, an active layer 132, a second semiconductor layer 133, the cathode electrode 135, and an encapsulation film 136, but the embodiments of the present disclosure are not limited thereto. For example, the first light-emitting element 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented with a group III-V compound semiconductor, a group II-VI compound semiconductor, or the like, and may be doped with impurities (or dopant). For example, one of the first semiconductor layer 131 and the second semiconductor layer 133 may be a semiconductor layer doped with n-type impurities and the other may be a semiconductor layer doped with p-type impurities, but the embodiments of the present disclosure are not limited thereto. For example, one or more of the first semiconductor layer 131 and the second semiconductor layer 133 may be layers in which a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like is doped with n-type impurities or p-type impurities, but the embodiments of the present disclosure are not limited thereto. For example, the n-type impurities may be silicon (Si), germanium (Ge), selenium (Se), carbon (C), tellurium (Te), tin (Sn), or the like, but the embodiments of the present disclosure are not limited thereto. For example, the p-type impurities may be magnesium (Mg), zinc (Zn), calcium (Ca), strontium (Sr), barium (Ba), beryllium (Be), or the like, but the embodiments of the present disclosure are not limited thereto.

For example, the first semiconductor layer 131 and the second semiconductor layer 133 may be a nitride semiconductor containing n-type impurities and a nitride semiconductor containing p-type impurities, respectively, but the embodiments of the present disclosure are not limited thereto. For example, the first semiconductor layer 131 may be a nitride semiconductor containing p-type impurities, and the second semiconductor layer 133 may be a nitride semiconductor containing n-type impurities, but the embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and emit light. For example, the active layer 132 may have any one of a single well structure, a multi-well structure, a single quantum well structure, a multi quantum well (MQW) structure, a quantum dot structure, and a quantum line structure, but the embodiments of the present disclosure are not limited thereto. For example, the active layer 132 may be composed of indium gallium nitride (InGaN) or gallium nitride (GaN), but the embodiments of the present disclosure are not limited thereto.

For another example, the active layer 132 may include a multi quantum well (MQW) structure having a well layer and a barrier layer having a higher band gap than the well layer. For example, the active layer 132 may include an InGaN well layer and an AlGaN barrier layer, but the embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be composed of a conductive material which may be eutectically bonded to the solder pattern SDP, but the embodiments of the present disclosure are not limited thereto. For example, the anode electrode 134 may be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present disclosure are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be composed of a transparent conductive material so that the light emitted from the light-emitting element ED may be directed toward an upper portion of the light-emitting element ED, but the embodiments of the present disclosure are not limited thereto. For example, the cathode electrode 135 may be composed of a material such as indium tin oxide (ITO), indium zinc oxide (IZO), or indium gallium zinc oxide (IGZO), but the embodiments of the present disclosure are not limited thereto.

The encapsulation film 136 may be disposed on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least portions of the anode electrode 134 and the cathode electrode 135, for example, an edge portion (or one side) of the anode electrode 134 and an edge portion (or one side) of the cathode electrode 135. Since at least a portion of the anode electrode 134 may be exposed from the encapsulation film 136, the anode electrode 134 and the solder pattern SDP may be connected. For example, since at least a portion of the cathode electrode 135 may be exposed from the encapsulation film 136, the cathode electrode 135 and the second electrode CE2 may be connected. For example, the encapsulation film 136 may be formed of an insulating material such as silicon nitride (SiNₓ) or silicon oxide (SiOₓ), but the embodiments of the present disclosure are not limited thereto.

For another example, the encapsulation film 136 may have a structure in which a reflective material is dispersed in a resin layer, but the embodiments of the present disclosure are not limited thereto. For example, the encapsulation film 136 may be manufactured as a reflector having various structures, but the embodiments of the present disclosure are not limited thereto. Since light emitted from the active layer 132 may be reflected upward by the encapsulation film 136, light extraction efficiency may be enhanced. For example, the encapsulation film 136 may be a reflective layer, but the embodiments of the present disclosure are not limited thereto.

According to the present disclosure, although the light-emitting element ED is described as having a vertical structure, the embodiments of the present disclosure are not limited thereto. For example, the light-emitting element ED may have a lateral structure or a flip chip structure.

Although the first light-emitting element 130 has been described with reference to FIG. 10, the second light-emitting element 140 and the third light-emitting element 150 may have substantially the same structure as the first light-emitting element 130. For example, the structures of the second light-emitting element 140 and the third light-emitting element 150 may be substantially the same as the first semiconductor layer 131, the active layer 132, the second semiconductor layer 133, the anode electrode 134, the cathode electrode 135, and the encapsulation film 136 of the first light-emitting element 130.

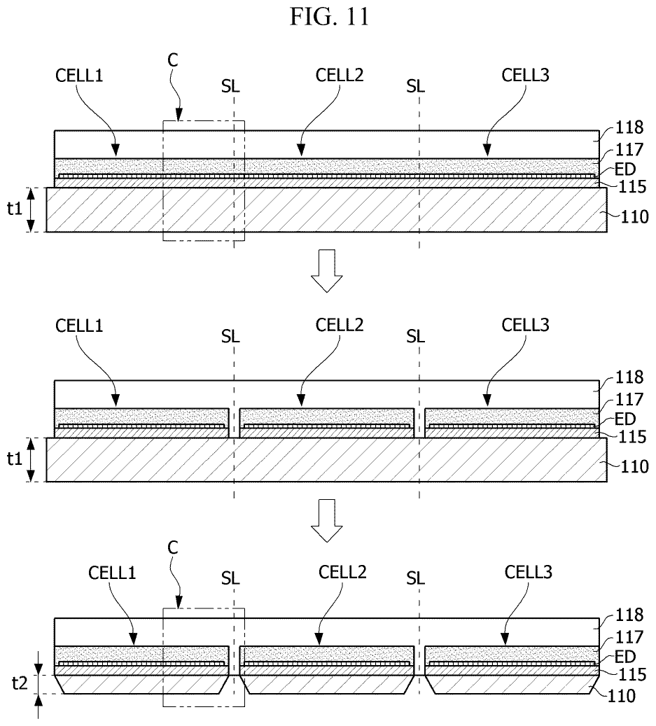

FIG. 11 is a view showing a plurality of cells formed on a mother substrate.

Referring to FIG. 11, a plurality of cells CELL1 to CELL3 may be formed simultaneously on a mother substrate 110 which is a large glass substrate. One cell may include a display region AA and a non-display region NA outside the display region AA of a single display panel.

First, an operation in which a circuit layer 115 is disposed on the mother substrate 110 may be included. The circuit layer 115 may include a plurality of protective layers, a plurality of insulating layers, a pixel driving circuit PD, and a plurality of first connection lines 121. The pixel driving circuit PD and the plurality of first connection lines 121 may be electrically connected to each other through contact holes disposed in the plurality of protective layers and/or the plurality of insulating layers.

Next, an operation in which a plurality of light-emitting elements ED are disposed on the circuit layer 115 may be included. When the plurality of light-emitting elements ED to be disposed are micro light-emitting elements, the plurality of light-emitting elements ED may be disposed through a transfer process using a bank BNK disposed on the circuit layer as an alignment key MK.

The plurality of light-emitting elements ED may be electrically connected to the plurality of first connection lines 121 of the circuit layer 115 through contact electrodes CCE, and may output an image by receiving a driving signal and/or a driving voltage from the pixel driving circuit PD.

Next, an operation in which a second inorganic film layer 116b is disposed may be included. For example, the second inorganic film layer 116b may be disposed on the plurality of signal lines TL, a plurality of first electrodes CE1, a plurality of contact electrodes CCE, and a third insulating layer 115c in the circuit layer 115. For example, the second inorganic film layer 116b may be disposed in the display region AA and the non-display region NA.

Next, an operation in which an optical layer 117 is disposed on the second inorganic film layer 116b and the circuit layer 115 to surround the light-emitting elements may be included.

The optical layer 117 may include a first optical layer 117a disposed to surround the plurality of light-emitting elements ED and a second optical layer 117b disposed to overlap the plurality of light-emitting elements ED and the first optical layer 117a on a second electrode CE2 and the plurality of light-emitting elements ED.

Next, an operation in which a first inorganic film layer 116a is additionally disposed on the optical layer 117 may be included. The first inorganic film layer 116a may have a first length and an exposed side surface in the non-display region NA, and the second inorganic film layer 116b may have a second length and an exposed side surface in the non-display region NA. The second length may be longer than the first length.

Next, a cover layer 118 may be disposed on the first inorganic film layer 116a and the optical layer 117. The cover layer 118 may protect the configuration under the cover layer 118. For example, the cover layer 118 may be composed of an organic insulating material, but the embodiments of the present disclosure are not limited thereto. For example, the cover layer 118 may be composed of a photoresist, a polyimide (PI)-based material, a photo acrylic-based material, or the like, but the embodiments of the present disclosure are not limited thereto. For example, the cover layer 118 may be an overcoating layer or an insulating layer, but the embodiments of the present disclosure are not limited thereto.

In order to separate the mother substrate 110 disposed up to the cover layer 118 in cell units, a laser trimming process may be performed. Further, a thickness of the mother substrate 110 may be reduced in an etching process, for example, from t1 to t2. In order to reduce the thickness of the mother substrate 110 and partially remove glass, a glass full-surface etching process and a selective glass etching process may be performed. The mother substrate 110, the circuit layer 115, the second inorganic film layer 116b, the optical layer 117, and the first inorganic film layer 116a may be cut with a laser beam along a preset intercell boundary line SL to separate a plurality of display panels from the mother substrate 110. The insulating layers of the circuit layer 115 and a side surface of the optical layer 117 may be exposed on at least one of surfaces of each of the display panels, and a stepped portion of the optical layer 117 may be present between the outermost ends of the first inorganic film layer 116a and the second inorganic film layer 116b and at least one of the outermost side surfaces of the mother substrate 110 or at least one of side surfaces of the mother substrate 110.

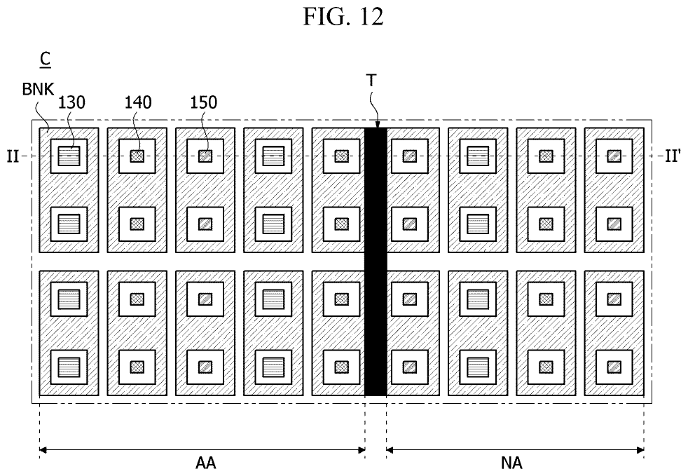

FIG. 12 is an enlarged plan view of portion C in FIG. 11.

Referring to FIG. 12, one separated cell according to the embodiment of the present disclosure may include a display region AA and a non-display region NA. The display region AA may include a plurality of light-emitting elements 130, 140, and 150, a second electrode CE2, a first optical layer 117a, a second optical layer 117b, and a third optical layer 117c. A non-display region NA may include the plurality of light-emitting elements 130, 140, and 150, the first optical layer 117a, the second optical layer 117b, and the third optical layer 117c.

The plurality of light-emitting elements 130, 140, and 150 disposed in the display region AA may emit light by a high potential power voltage applied to the first electrode as the plurality of second electrodes CE2 are disposed. The second electrodes CE2 may be formed to entirely cover a plurality of pixels to be common to the plurality of pixels. For example, the second electrode CE2 may be formed to be common only to the plurality of light-emitting elements 130, 140, and 150 disposed in each pixel.

The plurality of light-emitting elements 130, 140, and 150 disposed in the display region AA and the non-display region NA may include a first light-emitting element 130, a second light-emitting element 140, and a third light-emitting element 150. The first light-emitting element 130, the second light-emitting element 140, and the third light-emitting element 150 may respectively implement a first color, a second color, and a third color. The first to third colors may be any one of red, green, and blue selected so as not to overlap each other, but the embodiment of the present disclosure is not limited thereto. For example, the first color may be red, the second color may be green, and the third color may be blue, but the present disclosure is not limited thereto.

The non-display region NA may include a dummy region. The dummy region may include a dummy pixel including a plurality of dummy light-emitting elements. The second electrode CE2 may not be disposed in the non-display region NA where the plurality of dummy light-emitting elements are disposed. Accordingly, even when the high potential power voltage is applied to the first electrode disposed on the dummy light-emitting elements, the dummy light-emitting elements may not emit light.

A trench T may be disposed between the plurality of light-emitting elements 130, 140, and 150. The trench T may be disposed between the second light-emitting element 140 and the third light-emitting element 150 adjacent to each other, but the present disclosure is not limited thereto. As the trench T is disposed between the second light-emitting element 140 and the third light-emitting element 150 having relatively small sizes, the design margin of the display panel may be secured. Accordingly, the probability of the defective transfer of the light-emitting element in the manufacturing process of the display panel may be reduced. Accordingly, the productivity of the display device may be enhanced. Further, as the trench T is disposed, the display panel may be protected. For example, effects such as prevention of moisture penetration and the like can be implemented. Accordingly, the reliability of the display device may be enhanced.

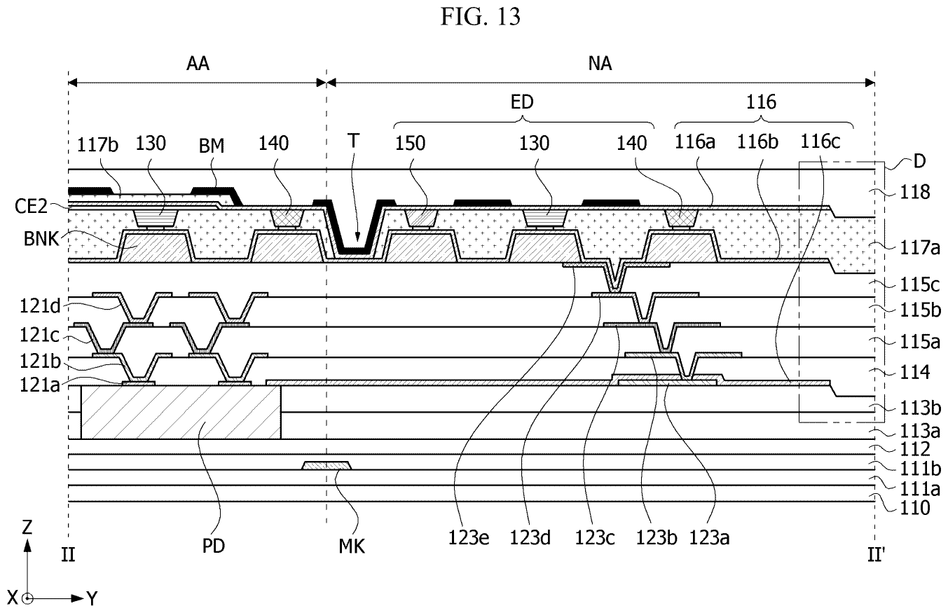

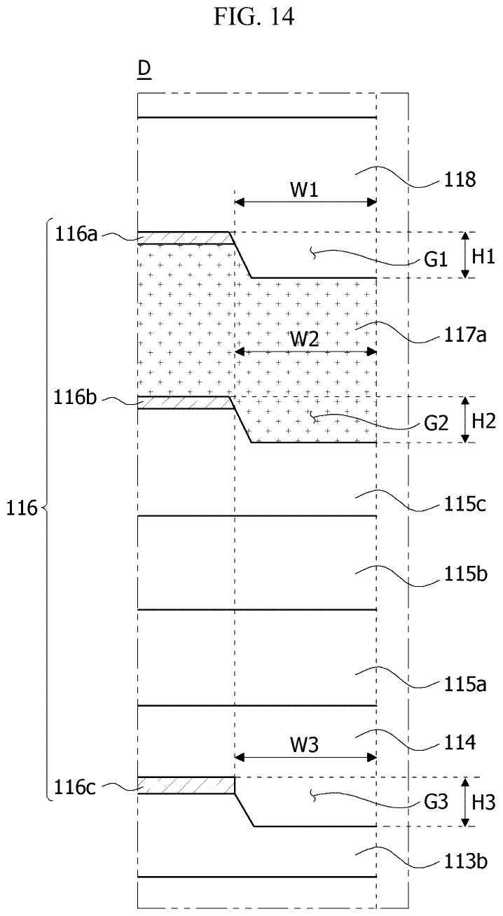

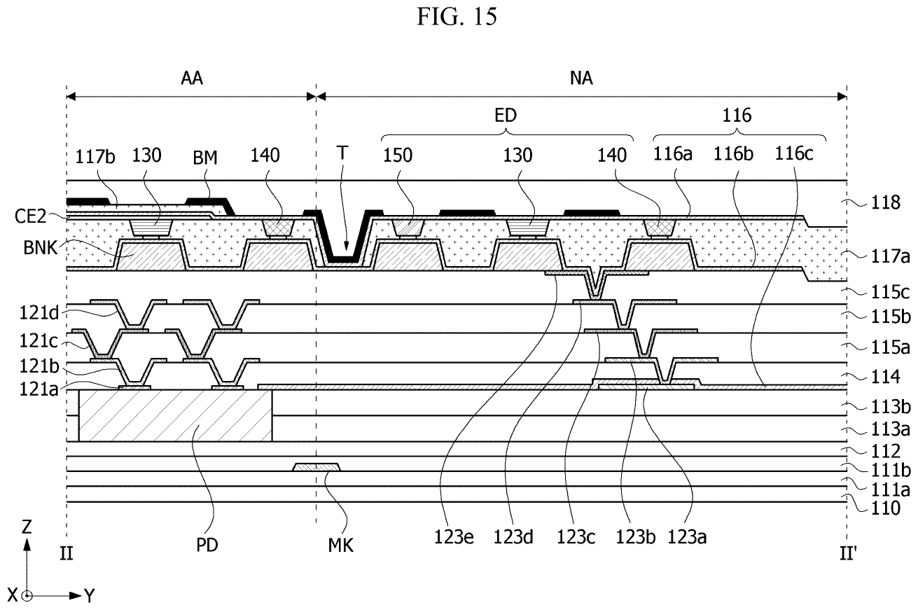

FIG. 13 is a cross-sectional view of the display device according to the embodiment of the present disclosure taken along line II-II′ in FIG. 12. FIG. 14 is an enlarged view of portion D in FIG. 13. FIG. 15 is a cross-sectional view of a display device according to a second embodiment of the present disclosure taken along line II-II′ in FIG. 12.

Referring to FIGS. 13 and 15, the display device 1000 may include a plurality of light-emitting elements 130, 140, and 150 disposed in the display region AA and the non-display region NA.

A circuit layer disposed in the display region AA may include a pixel driving circuit PD and a plurality of first connection lines 121. The plurality of first connection lines 121 may include a 1-1 connection line 121a, a 1-2 connection line 121b, a 1-3 connection line 121c, and a 1-4 connection line 121d, but the embodiments of the present disclosure are not limited thereto.

Each of the first connection lines 121a, 121b, 121c, and 121d may be electrically connected through a contact hole disposed in the circuit layer.

A third inorganic film layer 116c may be disposed between the second protective layer 113b and the third protective layer 114. The third inorganic film layer 116c may be formed on at least a portion of the upper portion of the pixel driving circuit PD of the display region AA and in the non-display region NA. The third inorganic film layer 116c may be formed to entirely cover the second protective layer 113b in the non-display region NA. As the third inorganic film layer 116c may protect the display device from moisture penetration from the outside of the display device 1000, the reliability of the display device 1000 may be enhanced.

The third inorganic film layer 116c may be composed of a single or multiple layers of silicon oxide (SiOₓ) or silicon nitride (SiNₓ) like the first inorganic film layer 116a and the second inorganic film layer 116b, but the embodiments of the present disclosure are not limited thereto. For example, the third inorganic film layer 116c may be a protective layer or an insulating layer, but the embodiments of the present disclosure are not limited thereto.

Referring to FIG. 14, in the non-display region NA, a plurality of inorganic film layers 116 may be etched and disposed before laser trimming is performed at an intercell boundary line SL where cells are trimmed with laser. For example, the third inorganic film layer 116c disposed on the second protective layer 113b may be etched while forming a third stepped portion G3 before a laser trimming process. Or, the third inorganic film layer 116c disposed on the intercell boundary line SL may be etched to dispose the third stepped portion G3. Similarly, the second inorganic film layer 116b disposed on the third insulating layer 115c may be etched while forming a second stepped portion G2 before the laser trimming process. Or, the second inorganic film layer 116b disposed on the intercell boundary line SL may be etched to dispose the second stepped portion G2. The first inorganic film layer 116a disposed on the first optical layer 117a may be etched while forming a first stepped portion G1 before the laser trimming process. Or, the first inorganic film layer 116a disposed on the intercell boundary line SL may be etched to dispose the first stepped portion G1.

The first stepped portion G1, the second stepped portion G2, and the third stepped portion G3 may be disposed with widths H1, H2, and H3 and lengths W1, W2, and W3, respectively.

The width H1, H2, and H3 and the length W1, W2, W3 of each stepped portion G1, G2, G3 may be adjusted. For example, in order to prevent moisture intrusion, the length W1 of the first stepped portion G1 may be shorter than the length of each of the other stepped portions G2 and G3. For another example, the length W2 and the width H2 of the second stepped portion G2 at the innermost side of the display panel may disposed to be longer than the lengths W1 and W3 and the widths H1 and H3 of each of the other stepped portions G1 and G3 respectively, but the embodiments of the present disclosure are not limited thereto.

As the plurality of inorganic film layers 116 are etched while forming the stepped portions G1, G2, and G3 before the laser trimming process, film peeling due to poor adhesion between the plurality of inorganic film layers 116 and the plurality of organic layers 113b, 115c, and 117a which may occur at the intercell boundary line SL during the laser trimming process may be prevented.

Referring to FIGS. 13 and 15 again, a plurality of anti-penetration lines 123 may be disposed in the non-display region NA. The anti-penetration lines 123 may be disposed to be electrically separated from the pixel driving circuit PD.

In order to prevent moisture which has penetrated from the outside through the insulating layer 115a, 115b, and 115c and the protective layer 113a, 113b, and 114 vulnerable to moisture from penetrating into the display region AA, the plurality of anti-penetration lines 123 may be disposed outside the display region AA.

For example, a first anti-penetration line 123a may be disposed on the second protective layer 113b. A second anti-penetration line 123b may be disposed on the third protective layer 114 and connected to the first anti-penetration line 123a through contact holes formed in the third protective layer 114 and the third inorganic film layer 116c.

A third anti-penetration line 123c may be disposed on the first insulating layer 115a and connected to the second anti-penetration line 123b through a contact hole formed in the first insulating layer 115a.

A fourth anti-penetration line 123d may be disposed on the second insulating layer 115b and connected to the third anti-penetration line 123c through a contact hole formed in the second insulating layer 115b.

A fifth anti-penetration line 123e may be disposed by etching a portion of the third insulating layer 115c and connected to the fourth anti-penetration line 123d through a contact hole formed in the third insulating layer 115c. For example, the contact holes which respectively connect the anti-penetration lines 123a to 123e may be disposed so as not to overlap in a height direction (for example, a Z-axis direction) of the display device. For example, the contact holes which respectively connect the anti-penetration lines 123a to 123e may partially overlap in the height direction (e.g., the Z-axis direction) of the display device.

The plurality of anti-penetration lines 123a to 123e may be formed of any one of a conductive material having excellent flexibility like the plurality of first connection lines 121 and the plurality of second connection lines 122, or any one of various conductive materials used in the display region AA. For example, the plurality of anti-penetration lines 123 may be composed of a conductive material having excellent flexibility such as gold (Au), silver (Ag), aluminum (Al), or the like, but the embodiments of the present disclosure are not limited thereto. For another example, the plurality of anti-penetration lines 123 may be composed of molybdenum (Mo), chromium (Cr), titanium (Ti), nickel (Ni), neodymium (Nd), copper (Cu), an alloy of silver (Ag) and magnesium (Mg), an alloy thereof, or the like, but the embodiments of the present disclosure are not limited thereto.

The display device 1000 may include a trench T. Referring to a coordinate system, a trench T may be disposed to extend in a first direction (for example, an X-axis direction). The non-display region NA may include the trench T. The trench T may be formed between the plurality of light-emitting elements 130, 140, and 150. The trench T may be formed between the plurality of dummy light-emitting elements (a plurality of light-emitting elements disposed in the non-display region NA).

The first optical layer 117a formed in the non-display region NA may include the trench T. The second optical layer 117b formed in the non-display region NA may include the trench T. The trench T may be formed as at least a portion of the first optical layer 117a and/or the second optical layer 117b is removed. The first inorganic film layer 116a may be disposed in the trench T. At least a portion of the black matrix BM may be disposed in the trench T.

As shown in FIG. 15, the third inorganic film layer 116c may be disposed up to the intercell boundary line SL without being etched. The embodiments of the present disclosure are not limited thereto, and for example, the first inorganic film layer 116a disposed on the first optical layer 117a or the second inorganic film layer 116b disposed on the third insulating layer 115c may be disposed to extend to an end of the intercell boundary line SL without being etched.

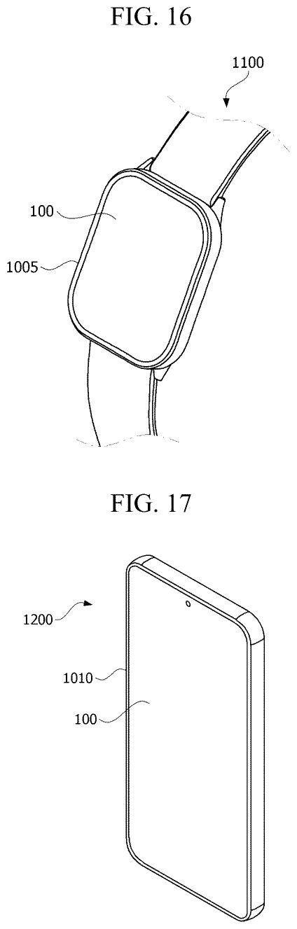

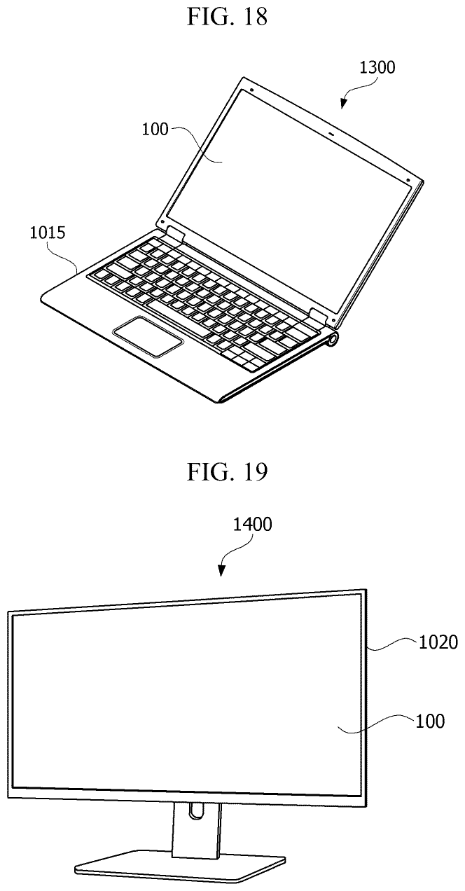

FIGS. 16 to 19 are views showing devices to which the display devices according to the embodiments of the present disclosure are applied.

Referring to FIGS. 16 to 19, the display devices 1000 according to the embodiments of the present disclosure may be included in various devices or electronic devices.

For example, referring to FIGS. 16 to 19, various electronic devices may include a wearable device 1100, a mobile device 1200, a notebook 1300, and a monitor or television (TV) 1400, but the embodiments of the present disclosure are not limited thereto.

The wearable device 1100, the mobile device 1200, the notebook 1300, and the monitor or TV 1400 may respectively include case portions 1005, 1010, 1015, and 1020, and the above-described display panels 100 and display devices 1000 according to the embodiments of the present disclosure.

For example, the display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation device, a vehicle display device, a theater display device, a television, a wallpaper apparatus, a signage apparatus, a gaming apparatus, a notebook, a monitor, a camera, a camcorder, a home appliance, and the like.

The display device according to one or more embodiments of the present disclosure may be described as follows.

A display panel according to the embodiment of the present disclosure may include a substrate, a circuit layer disposed on the substrate, a plurality of light-emitting elements disposed on the circuit layer and electrically connected to the circuit layer, an optical layer surrounding the light-emitting elements, a second inorganic film layer disposed under the optical layer, and a first inorganic film layer disposed on the optical layer, wherein insulating layers of the circuit layer and a side surface of the optical layer may be exposed on at least one of side surfaces of the substrate, and wherein a stepped portion of the optical layer may be present between outermost ends of the first inorganic film layer and the second inorganic film layer and at least one of outermost side surfaces of the substrate.

In the display panel according to the embodiment, the substrate may include a display region and a non-display region disposed outside the display region.

In the display panel according to the embodiment, the first inorganic film layer may have a first length and an exposed side surface in the non-display region, and the second inorganic film layer may have a second length and an exposed side surface in the non-display region.

In the display panel according to the embodiment, the second length may be longer than the first length.

A method of manufacturing a display panel according to the embodiment may include disposing a circuit layer on a mother substrate, disposing a plurality of light-emitting elements electrically connected to the circuit layer on the circuit layer, disposing a second inorganic film layer on the circuit layer, disposing an optical layer on the second inorganic film layer and the circuit layer to surround the light-emitting elements, disposing a first inorganic film layer on the optical layer, and cutting the mother substrate, the circuit layer, the second inorganic film layer, the optical layer, and the first inorganic film layer with a laser beam along a preset intercell boundary line to separate a plurality of display panels from the mother substrate, wherein insulating layers of the circuit layer and a side surface of the optical layer may be exposed on at least one of surfaces of each of the display panels, and wherein a stepped portion of the optical layer may be present between outermost ends of the first inorganic film layer and the second inorganic film layer and at least one of side surfaces of the mother substrate.

The method of manufacturing the display panel according to the embodiment may further include etching the first inorganic film layer disposed on the preset intercell boundary line to dispose the stepped portion between the disposing of the first inorganic film layer and the disposing of the optical layer.

The method of manufacturing the display panel according to the embodiment may further include etching the second inorganic film layer disposed on the preset intercell boundary line to dispose the stepped portion between the disposing of the second inorganic film layer and the separating of the plurality of display panels.

In the method of manufacturing the display panel according to the embodiment, the disposing of the circuit layer may further include disposing a third inorganic film layer between protective layers in the circuit layer.

The method of manufacturing the display panel according to the embodiment may further include etching the second inorganic film layer disposed on the preset intercell boundary line to dispose the stepped portion between the disposing of the third inorganic film layer and the disposing of the plurality of light-emitting elements on the circuit layer.

In the display panel according to the embodiment, the light-emitting elements may include a first light-emitting element that emits light in a first wavelength band, a second light-emitting element that emits light in a second wavelength band, and a third light-emitting element that emits light in a third wavelength band, and a size of at least one of the first light-emitting element, the second light-emitting element, and the third light-emitting element may be different from sizes of the other light-emitting elements.

In the display panel according to the embodiment, the size of the first light-emitting element may be larger than each of the sizes of the second light-emitting element and the third light-emitting element.

In the display panel according to the embodiment, the sizes of the second light-emitting element and the third light-emitting element may be substantially the same.

In the display panel according to the embodiment, the first light-emitting element, the second light-emitting element, and the third light-emitting element may all be inorganic light-emitting elements.

According to the present disclosure, reliability can be secured by reducing a ratio of the light-emitting elements transferred as defective light-emitting elements when light-emitting elements are transferred to a panel of a display device.

According to the present disclosure, since the display device is protected from moisture penetration from the outside of the display device, the reliability of the display device can be enhanced.

Since moisture penetration from the outside of the display device is prevented, the lifespan of the display device can be enhanced. Accordingly, power consumption can be reduced and low-power driving can be achieved in the long term.

The effects according to the present disclosure are not limited to the above-mentioned effects, and other effects which are not mentioned can be clearly understood by those skilled in the art from the disclosure to be described above.

Although the embodiments of the present disclosure have been described in more detail with reference to the accompanying drawings, the present disclosure is not necessarily limited to these embodiments, and may be variously modified without departing from the technical spirit of the present disclosure.

Accordingly, the embodiments disclosed in the present disclosure are not intended to limit the technical spirit of the present disclosure but illustrate it, and the scope of the technical spirit of the present disclosure is not limited by these embodiments.

Accordingly, the above-described embodiments should be understood as examples in all aspects and not restrictive.

The scope of the present disclosure should be interpreted by the claims, and it should be interpreted that all technical ideas within the equivalent range are included in the scope of the present disclosure.

What is claimed is:

1. A display panel, comprising:
a substrate;
a circuit layer disposed on the substrate;
a plurality of light-emitting elements disposed on the circuit layer and electrically connected to the circuit layer;
an optical layer surrounding the light-emitting elements;
a first inorganic film layer disposed on the optical layer; and
a second inorganic film layer disposed under the optical layer,
wherein insulating layers of the circuit layer and a side surface of the optical layer are exposed on at least one of side surfaces of the substrate, and
wherein a stepped portion of the optical layer is present between outermost ends of the first inorganic film layer and the second inorganic film layer and at least one of outermost side surfaces of the substrate.

2. The display panel of claim 1, comprising: a display region and a non-display region disposed outside the display region.

3. The display panel of claim 2, wherein the first inorganic film layer has a first length and an exposed side surface in the non-display region, and
the second inorganic film layer has a second length and an exposed side surface in the non-display region.

4. The display panel of claim 3, wherein the second length is longer than the first length.

5. The display panel of claim 1, wherein the plurality of light-emitting elements include:
a first light-emitting element configured to emit light in a first wavelength band;
a second light-emitting element configured to emit light in a second wavelength band; and
a third light-emitting element configured to emit light in a third wavelength band, and
wherein a size of at least one of the first light-emitting element, the second light-emitting element, and the third light-emitting element is different from sizes of the other light-emitting elements.

6. The display panel of claim 5, wherein the size of the first light-emitting element is larger than each of the sizes of the second light-emitting element and the third light-emitting element.

7. The display panel of claim 6, wherein the sizes of the second light-emitting element and the third light-emitting element are same.

8. The display panel of claim 5, wherein the first light-emitting element, the second light-emitting element, and the third light-emitting element are all inorganic light-emitting elements.

9. The display panel of claim 5, wherein the first light-emitting element includes:
an anode electrode;
a first semiconductor layer disposed on the anode electrode;
an active layer disposed on the first semiconductor layer;
a second semiconductor layer disposed on the active layer;
a cathode electrode disposed on the second semiconductor layer; and
a solder pattern disposed under the anode electrode,
wherein the anode electrode is electrically connected by eutectic bonding using the solder pattern, and
wherein the second light-emitting element and the third light-emitting element are disposed in a same structure as the first light-emitting element.

10. The display panel of claim 2, further comprising:
a plurality of pixel driving circuits disposed in the display region; and
a plurality of anti-penetration lines disposed in the non-display region,
wherein the anti-penetration lines are disposed to be electrically separated from the pixel driving circuits.

11. A display device, comprising:
the display panel of claim 1;
a polarization layer disposed on the display panel; and
a cover member disposed on the polarization layer.

12. A method of manufacturing a display panel, comprising:
disposing a circuit layer on a mother substrate;
disposing a plurality of light-emitting elements electrically connected to the circuit layer on the circuit layer;
disposing a second inorganic film layer on the circuit layer;
disposing an optical layer on the second inorganic film layer and the circuit layer to surround the light-emitting elements;
disposing a first inorganic film layer on the optical layer; and
cutting the mother substrate, the circuit layer, the second inorganic film layer, the optical layer, and the first inorganic film layer with a laser beam along a preset intercell boundary line to separate a plurality of display panels from the mother substrate,
wherein insulating layers of the circuit layer and a side surface of the optical layer are exposed on at least one of surfaces of each of the display panels, and
wherein a stepped portion of the optical layer is present between outermost ends of the first inorganic film layer and the second inorganic film layer and at least one of side surfaces of the mother substrate.

13. The method of claim 12, further comprising etching the first inorganic film layer disposed on the preset intercell boundary line to dispose the stepped portion between the disposing of the first inorganic film layer and the disposing of the optical layer.

14. The method of claim 12, further comprising etching the second inorganic film layer disposed on the preset intercell boundary line to dispose the stepped portion between the disposing of the second inorganic film layer and the separating of the plurality of display panels.

15. The method of claim 12, wherein the disposing of the circuit layer further includes disposing a third inorganic film layer between protective layers in the circuit layer.

16. The method of claim 15, further comprising etching the second inorganic film layer disposed on the preset intercell boundary line to dispose the stepped portion between the disposing of the third inorganic film layer and the disposing of the plurality of light-emitting elements on the circuit layer.
